(19) United States
(12) Patent Application Publication
(10) Pub. No.: US 2024/0224753 A1
(43) Pub. Date: Jul. 4, 2024

(54) DISPLAY APPARATUS

(71) Applicant: LG Display Co., Ltd., Seoul (KR)

(72) Inventors: Sejong SEONG, Paju-si (KR); SeHong PARK, Paju-si (KR); Wonrae KIM, Paju-si (KR); Hyemin PARK, Paju-si (KR); SeoHyun NAM, Paju-si (KR)

(21) Appl. No.: 18/469,970

(22) Filed: Sep. 19, 2023

(30) Foreign Application Priority Data
Dec. 28, 2022 (KR) 10-2022-0187362

(51) Int. Cl. H10K 59/80; H10K 59/131; H10K 59/35

(52) U.S. Cl. CPC H10K 59/879; H10K 59/131; H10K 59/351

(57) ABSTRACT

A display apparatus is provided, which may improve light extraction efficiency of light emitted from a light emitting element layer. The display apparatus comprises a substrate having a plurality of pixels, each of the plurality of pixels having a plurality of subpixels, a pattern portion disposed on the substrate, a reflective portion on the pattern portion, and a plurality of lines provided below the pattern portion, for driving the plurality of subpixels, wherein the plurality of subpixels include a light emission area and a non-light emission area adjacent to the light emission area, the non-light emission area includes a first area adjacent to the light emission area and a second area adjacent to the first area, and the first area is between the second area and the light emission area, and at least one of the plurality of lines is disposed to at least partially overlap the second area.

### CROSS-REFERENCE TO RELATED APPLICATIONS

This application claims the benefit of the Korean Patent Application No. 10-2022-0187362 filed on Dec. 28, 2022, which is hereby incorporated by reference as if fully set forth herein.

### BACKGROUND

### Technical Field

The present disclosure relates to a display apparatus for displaying an image.

### Description of the Related Art

Since an organic light emitting display apparatus has a high response speed and low power consumption and self-emits light without requiring a separate light source unlike a liquid crystal display apparatus, there is no problem in a viewing angle and thus the organic light emitting display apparatus has received attention as a next-generation flat panel display apparatus.

Such a display apparatus displays an image through light emission of a light emitting element layer that includes a light emitting layer interposed between two electrodes.

### BRIEF SUMMARY

Meanwhile, the inventors have realized that light extraction efficiency of the display apparatus in the related art is reduced as some of light emitted from the light emitting element layer is not emitted to the outside due to total reflection on the interface between the light emitting layer and an electrode and/or between a substrate and an air layer. The present disclosure has been made in view of the various technical problems in the related art including the above-identified problems.

Various embodiments of the present disclosure provide a display apparatus that may improve light extraction efficiency of light emitted from a light emitting element layer.

Various embodiments of the present disclosure provide a display apparatus in which light extraction efficiency may be further improved through light extraction from a non-light emission area.

Various embodiments of the present disclosure provide a display apparatus in which light may be extracted from a non-light emission area adjacent to a corner portion of a light emission area.

Various embodiments of the present disclosure provide a display apparatus in which luminance and/or viewing angle deviation of a plurality of subpixels may be reduced or minimized.

Various embodiments of the present disclosure provide a display apparatus in which an aperture ratio of at least one or more of a plurality of subpixels may be improved.

Various embodiments of the present disclosure provide a display apparatus in which afterimage lifespan of a light emitting layer may be improved.

Various embodiments of the present disclosure as mentioned above, additional technical benefits and features of the present disclosure will be clearly understood by those skilled in the art from the following description of the present disclosure.

In accordance with an aspect of the present disclosure, the above and other objects can be accomplished by the provision of a display apparatus comprising a substrate having a plurality of pixels, each of the plurality of pixels having a plurality of subpixels, a pattern portion disposed on the substrate, a reflective portion on the pattern portion, and a plurality of lines provided below the pattern portion, for driving the plurality of subpixels, wherein the plurality of subpixels include a light emission area and a non-light emission area adjacent to the light emission area, the non-light emission area includes a first area adjacent to the light emission area and a second area adjacent to the first area, and the first area is between the second area and the light emission area, and at least one of the plurality of lines is disposed to at least partially overlap the second area.

In accordance with another aspect of the present disclosure, the above and other objects can be accomplished by the provision of a display apparatus comprising a substrate having a plurality of pixels, each of the plurality of pixels having a plurality of subpixels, a pattern portion disposed on the substrate, a reflective portion on the pattern portion, and a plurality of lines provided below the pattern portion, for driving the plurality of subpixels, wherein the plurality of subpixels include a light emission area and an opening area overlapped with the light emission area between the plurality of lines, and a width of the opening area of one subpixel of the plurality of subpixels is wider than that of the light emission area of the one subpixel.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a schematic plan view illustrating a display apparatus according to one embodiment of the present disclosure;

FIG. 2 is a schematic plan view illustrating one pixel shown in FIG. 1;

FIG. 3 is a schematic cross-sectional view taken along line I-I′ shown in FIG. 2;

FIG. 4 is a schematic cross-sectional view taken along line II-II′ shown in FIG. 2;

FIG. 5 is an image illustrating light extraction characteristics of a non-light emission area of a display apparatus according to one embodiment of the present disclosure;

FIG. 6 is schematic cross-sectional view taken along line III-III′ shown in FIG. 2;

FIG. 7 is a schematic cross-sectional view taken along line IV-IV′ shown in FIG. 2;

FIG. 8 is a schematic cross-sectional view taken along line V-V′ shown in FIG. 2;

FIG. 9 is a schematic cross-sectional view taken along line VI-VI′ shown in FIG. 2; and

FIG. 10 is a schematic modified example taken along line VI-VI′ shown in FIG. 2.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings.

The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a dimension (e.g., length, width, height, thickness, radius, diameter, area, etc.), a ratio, an angle, and a number disclosed in the drawings for describing embodiments of the present disclosure are merely an example, and thus, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In the following description, when the detailed description of the relevant known function or configuration is determined to unnecessarily obscure the important point of the present disclosure, the detailed description will be omitted.

In a case where ‘comprise,’ ‘have,’ and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when a position relation between two parts is described as ‘on˜,’ ‘over˜,’ ‘under˜,’ and ‘next˜,’ one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just” or “direct” is used.

It will be understood that, although the terms “first.” “second,” etc., may be used herein to describe various elements, these elements should not be limited by these terms.

These terms are only used to distinguish one element from another. For example, a first element could be termed a second element, and, similarly, a second element could be termed a first element, without departing from the scope of the present disclosure.

“X-axis direction,” “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

The term “A and/or B” should be understood as including only A, or only B, or both A and B.

Features of various embodiments of the present disclosure may be partially or overall coupled to or combined with each other and may be variously inter-operated with each other and driven technically as those skilled in the art can sufficiently understand.

The embodiments of the present disclosure may be carried out independently from each other or may be carried out together in co-dependent relationship.

Hereinafter, the preferred embodiments of the present disclosure will be described in detail with reference to the accompanying drawings.

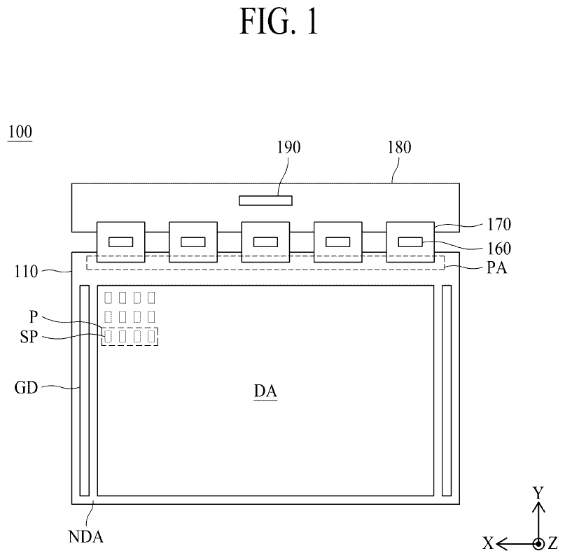

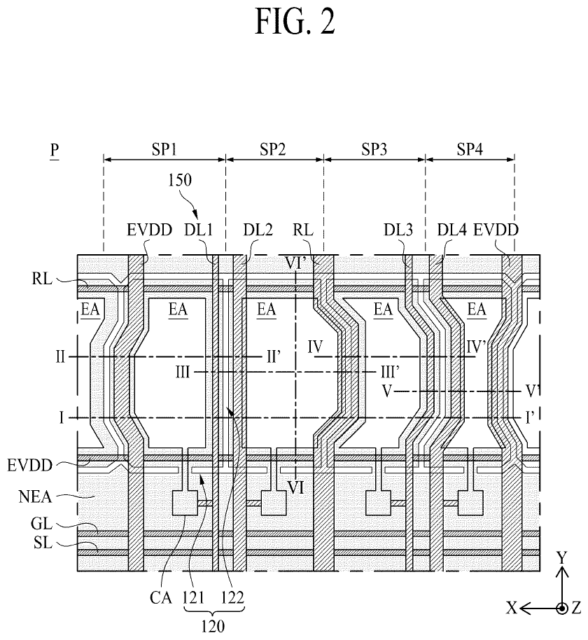

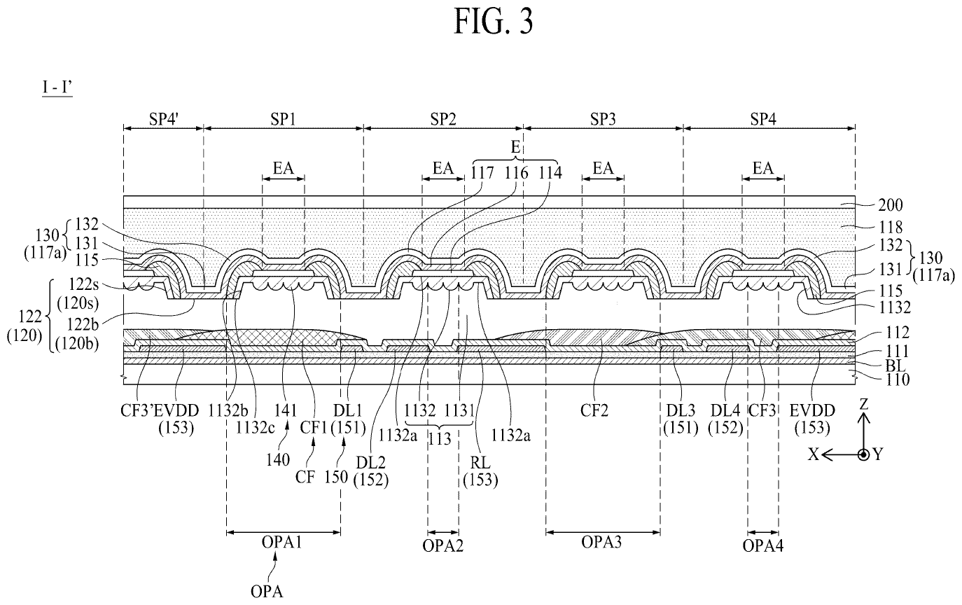

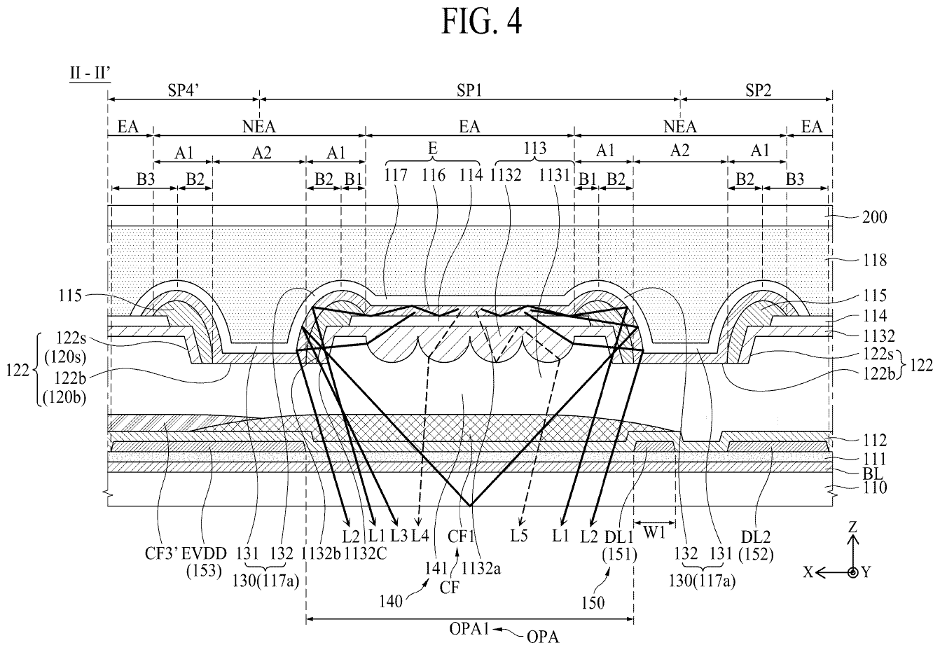

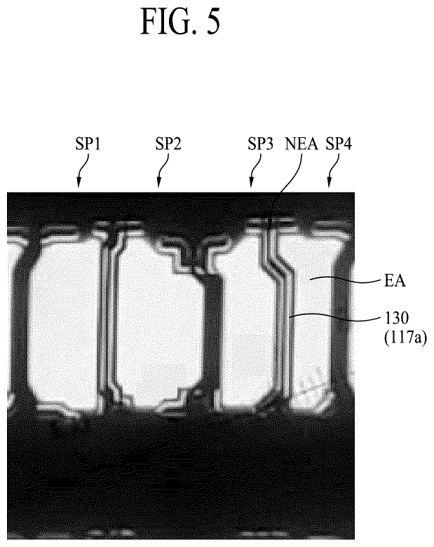

FIG. 1 is a schematic plan view illustrating a display apparatus according to one embodiment of the present disclosure, FIG. 2 is a schematic plan view illustrating one pixel shown in FIG. 1. FIG. 3 is a schematic cross-sectional view taken along line I-I′ shown in FIG. 2, FIG. 4 is a schematic cross-sectional view taken along line II-II′ shown in FIG. 2, and FIG. 5 is an image illustrating light extraction characteristics of a non-light emission area of a display apparatus according to one embodiment of the present disclosure.

Referring to FIGS. 1 to 5, a display apparatus 100 according to one embodiment of the present disclosure includes a substrate 110 having a plurality of pixels P, each of which has a plurality of subpixels SP, a pattern portion 120 disposed on the substrate 110 and formed to be concave (or have a concave shape) between the plurality of subpixels SP, a reflective portion 130 on the pattern portion 120, and a plurality of lines 150 provided under the pattern portion 120 and for driving the plurality of subpixels SP.

The plurality of subpixels SP may include a light emission area EA and a non-light emission area NEA adjacent to the light emission area EA. The light emission area EA is an area from which light is emitted, and may be included in a display area DA. The non-light emission area NEA is an area from which light is not emitted, and may be an area adjacent to the light emission area EA. The non-light emission area NEA may be expressed as a term of a peripheral area.

The non-light emission area NEA according to one example may include a first area A1 adjacent to the light emission area EA and a second area A2 adjacent to the first area A1, and the second area A2 may be spaced apart from the light emission area EA by the first area A1, that is, the first area A1 may be between the second area A2 and the light emission area EA. The first area A1 according to one example may be a bank area in which a bank for defining the light emission area EA is disposed. The second area A2 according to one example may be a bank-less area in which a bank is not disposed.

In the display apparatus 100 according to one embodiment of the present disclosure, a plurality of lines 150 may be disposed in one of the plurality of subpixels SP to overlap a second area A2. Therefore, the display apparatus 100 according to one embodiment of the present disclosure includes the subpixel SP in which the plurality of lines 150 do not cover the light emission area EA (or do not overlap the light emission area EA), so that an aperture ratio may be enlarged as compared with the case that each of the light emission areas of the plurality of subpixels is covered by the line, whereby luminance may be improved.

For example, as shown in FIG. 3, the display apparatus 100 according to one embodiment of the present disclosure may include first to fourth subpixels SP1 to SP4, wherein the first subpixel SP1 and the third subpixel SP3 may be provided so that the light emission area EA does not overlap the plurality of lines 150 in a thickness direction of the substrate 110, and the second subpixel SP2 and the fourth subpixel SP4 may be provided so that a portion of the light emission area EA overlaps the plurality of lines 150 in the thickness direction of the substrate 110.

Therefore, as shown in FIG. 3, the first subpixel SP1 may be provided so that a width of a first opening area OPA1, which is defined by a pixel power line EVDD (or a third line 153) and a first data line DL1 (or the first line 151), is wider than a width of the light emission area EA, which is defined by the bank 115.

A width of a second opening area OPA2 between a second data line DL2 and a reference line RL in the second subpixel SP2 may be narrower than a width of the light emission area EA of the second subpixel SP2. In this case, the width of the first opening area OPA1 of the first subpixel SP1 may be greater than that of the second opening area OPA2 of the second subpixel SP2.

A width of a third opening area OPA3 between a third data line DL3 and the reference line RL in the third subpixel SP3 may be wider than a width of the light emission area EA of the third subpixel SP3.

A width of a fourth opening area OPA4 between a fourth data line DL4 and the pixel power line EVDD in the fourth subpixel SP4 may be narrower than a width of the light emission area EA of the fourth subpixel SP4. In this case, the width of the third opening area OPA3 of the third subpixel SP3 in the third subpixel SP3 may be wider than that of the fourth opening area OPA4 of the fourth subpixel SP4.

In the display apparatus 100 according to one embodiment of the present disclosure, since the aperture ratio of one or more of the plurality of subpixels SP may be increased, afterimage lifespan of the light emitting layer may be improved. In this case, “one or more” of the plurality of subpixels may mean one or two subpixels.

Meanwhile, since a wide line, for example, the pixel power line EVDD has no option but to be included in the plurality of lines 150, one or two subpixels of the plurality of subpixels SP may have a relatively small aperture ratio. Unlike the data line DL, since the pixel power line EVDD is involved in driving of all of the plurality of subpixels SP, for example, four subpixels SP, its width may be wider than the width of the data line DL. As a result, in the display apparatus 100 according to one embodiment of the present disclosure, since an aperture ratio of some subpixels (or one or two subpixels) of the plurality of subpixels SP may be increased through proper arrangement of lines having a wide width and lines a narrow width, luminance and afterimage lifespan may be improved.

Also, in the display apparatus 100 according to one embodiment of the present disclosure, based on the light emission area EA (or opening area) of each of the subpixels SP, the plurality of lines 150 may be disposed in a symmetric position (or symmetrically) so that luminance and/or viewing angle deviation may be reduced or minimized.

The display apparatus 100 according to one embodiment of the present disclosure may include a first sub-area B1 from an upper surface (or bank ridge) of the bank 115 (shown in FIG. 4), which is the farthest from the substrate 110, to an end of the light emission area EA, which is adjacent to the bank 115, a second sub-area B2 from the bank ridge to an end of the bank 115, which is adjacent to the second area A2, and a third sub-area B3 from the bank ridge to an edge of the opening area (or opening), which is adjacent to the bank 115. As shown in FIG. 4, the edge of the opening area (or opening) may be positioned in the light emission area EA. Therefore, a summed width of a width of the third sub-area B3 and a width of the second sub-area B2 may be wider than a width of the first area A1. The opening area according to one example may mean an area between the lines 150 provided on both sides of the light emission area EA of each of the subpixels SP and/or an area between the lines 150 provided to overlap a portion of the light emission area EA of each of the subpixels SP.

Referring to FIG. 4, in the first subpixel SP1, the width of the first opening area OPA1 may be wider than that of the light emission area EA defined by the bank 115, and the pixel power line EVDD (or the third line 153) and the first data line DL1 (or the first line 151) may be disposed symmetrically based on the light emission area EA. Therefore, in the first subpixel SP1, a summed width of the width of the first sub-area B1 and the width of the second sub-area B2 may be the same as the width of the first area A1.

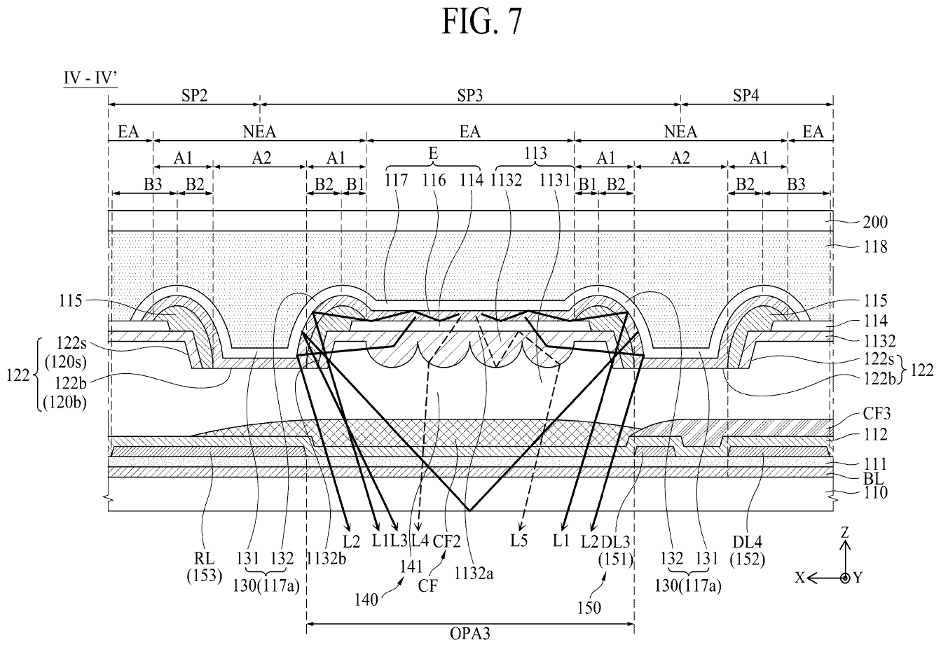

As shown in FIG. 3, since the third subpixel SP3 is provided in a structure the same as or similar to that of the first subpixel SP1, the third data line DL3 and the reference line RL may be disposed symmetrically based on the light emission area EA. Therefore, as shown in FIG. 7, in the third subpixel SP3, the summed width of the width of the first sub-area B1 and the width of the second sub-area B2 may be the same as the width of the first sub-area A1.

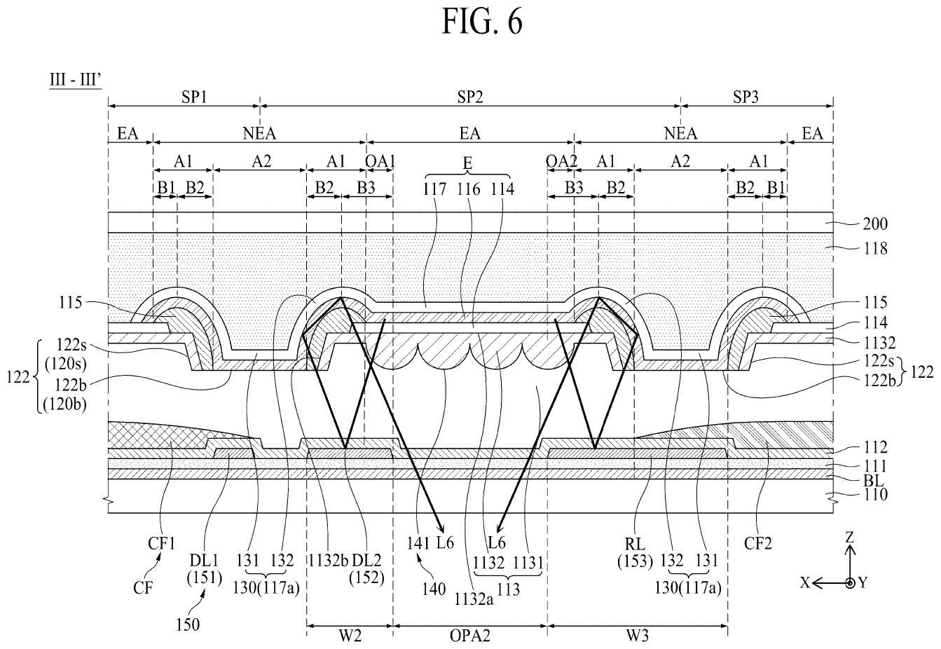

Referring to FIG. 6, in the second subpixel SP2, the width of the second opening area OPA2 is narrower than the width of the light emission area EA defined by the bank 115, and the second data line DL2 and the reference line RL may be disposed symmetrically based on the second opening area OPA2. Therefore, in the second subpixel SP2, the summed width of the width of the second sub-area B2 and the width of the third sub-area B3 may be wider than the width of the first area A1.

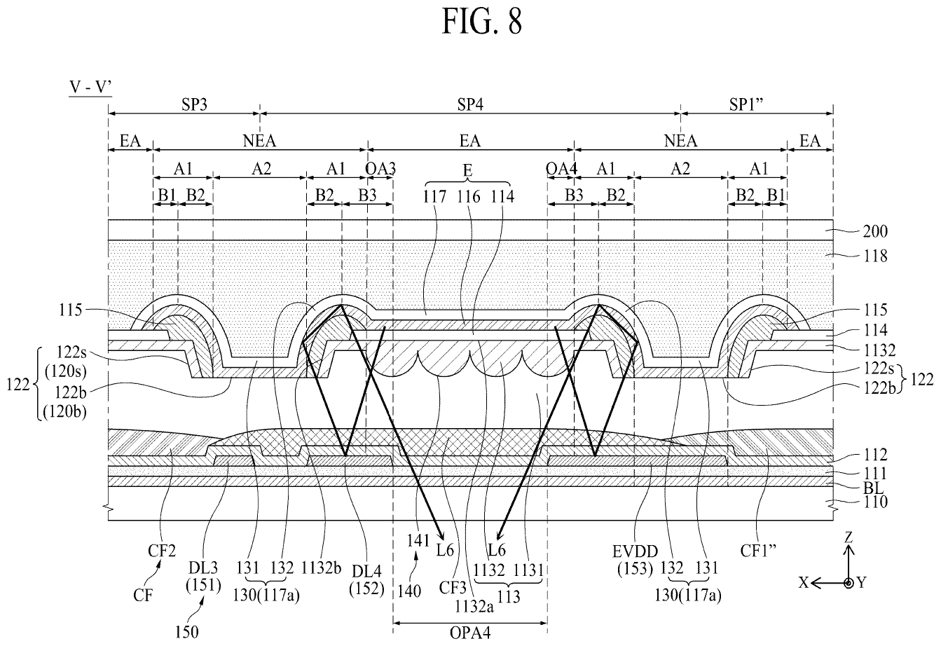

As shown in FIG. 3, since the fourth subpixel SP4 is provided in a structure the same as or similar to that of the second subpixel SP2, the fourth data line DLA and the pixel power line EVDD may be disposed symmetrically based on the fourth opening area OPA4. Therefore, as shown in FIG. 8, in the fourth subpixel SP4, the summed width of the width of the second sub-area B2 and the width of the third sub-area B3 may be wider than the width of the first area A1.

Meanwhile, the plurality of lines 150 may be provided below the pattern portion 120. At least a portion of each of the plurality of lines 150 may overlap the pattern portion 120 below the pattern portion 120. For example, as shown in FIG. 4, the first line 151 (or the first data line DL1) having a first width W1 may overlap the bottom surface 120b of the pattern portion 120. As shown in FIG. 6, the second line 152 (or the second data line DL2) having a second width W2 wider than the first width W1 may partially overlap the bottom surface 120b and the inclined surface 120s of the pattern portion 120. The third line 153 (or the pixel power line EVDD or the reference line RL) having a third width W3 wider than the second width W2 may partially overlap the bottom surface 120b and the inclined surface 120s of the pattern portion 120.

The pattern portion 120 may be provided to surround the light emission area EA. Therefore, the plurality of lines 150 may be also provided to surround the light emission area EA. In the display apparatus 100 according to one embodiment of the present disclosure, the plurality of lines 150 may be disposed to partially overlap the light emission area EA or so as not to overlap the light emission area EA, so that the aperture ratio of one of the plurality of subpixels SP may be provided to be greater than that of the other subpixel SP, whereby luminance may be improved.

Meanwhile, the display apparatus 100 according to one embodiment of the present disclosure may include three lines having different widths. For example, the three lines may be a first data line DL1, a second data line DL2 and a pixel power line EVDD. Also, the display apparatus 100 according to one embodiment of the present disclosure may further include a third data line DL3 having the same width as that of the first data line DL1, a fourth data line DLA having the same width as that of the second data line DL2, a pixel power line EVDD and a reference line RL. The first line 151 may be the first data line DL1 and the third data line DL3. The second line 152 may be the second data line DL2 and the fourth data line DLA. The third line 153 may be the pixel power line EVDD and the reference line RL. The first data line DL1 may be a line for driving the first subpixel SP1 that is a red subpixel, which will be described later. The second data line DL2 may be a line for driving the second subpixel SP2 that is a white subpixel, which will be described later. The third data line DL3 may be a line for driving the third subpixel SP3 that is a blue subpixel, which will be described later. The fourth data line DLA may be a line for driving the fourth subpixel SP4 that is a green subpixel, which will be described later. Each of the pixel power line EVDD and the reference line RL may be a line involved in all of the first to fourth subpixels SP1, SP2, SP3 and SP4. Therefore, the third line 153 may be provided to have a wider width than the first line 151 and the second line 152.

As shown in FIG. 3, in the display apparatus 100 according to one embodiment of the present disclosure, the first line 151 and the third line 153 may be disposed to overlap the second area A2 of one of the plurality of subpixels, so that an aperture ratio of the one of the plurality of subpixels may be relatively greater than that of the other subpixels. In addition, the second line 152 and the third line 153 may be disposed to overlap the first area A1 and a portion of the light emission area EA of another one of the plurality of subpixels, so that an aperture ratio of the another one of the plurality of subpixels may be relatively smaller than that of the one subpixel.

In the display apparatus 100 according to one embodiment of the present disclosure, as shown in FIG. 3, the pixel power line EVDD, the first data line DL1, the second data line DL2, the reference line RL, the third data line DL3, the fourth data line DLA and the pixel power line EVDD may be sequentially disposed in the first direction (X-axis direction) in one pixel. Therefore, each of the subpixels SP may be provided so that a line (or the third line 153) having a wide width in the first direction (X-axis direction) and a line (or the first line 151 or the second line 152) having a narrow width are disposed on both sides of the light emission area EA. Through such a structure, the display apparatus 100 according to one embodiment of the present disclosure may be provided so that among the plurality of subpixels, for example, four subpixels SP1, SP2, SP3 and SP4, the aperture ratio of the first subpixel SP1 and the third subpixel SP3 may be greater than that of the second subpixel SP2 and the fourth subpixel SP4. Therefore, the display apparatus 100 according to one embodiment of the present disclosure may improve light efficiency, that is, luminance as compared with the case that all of the plurality of subpixels have a narrow light emission area.

Meanwhile, the aperture ratio of the first subpixel SP1 and/or the third subpixel SP3 is greater than that of the second subpixel SP2 and/or the fourth subpixel SP4, this is because that the white subpixel (or the second subpixel SP2) and the green subpixel (or the fourth subpixel SP4) have color visibility relatively stronger than that of the red subpixel (or the first subpixel SP1) and the blue subpixel (or the third subpixel SP3). Therefore, in the display apparatus 100 according to one embodiment of the present disclosure, the first subpixel SP1 and the third subpixel SP3, which have relatively weak color visibility, are provided to have the aperture ratio greater than that of the second subpixel SP2 and the fourth subpixel SP4, whereby a luminance deviation between the subpixels SP may be reduced. In this case, the aperture ratio refers to a size of an opening area, and the opening area may refer to an area between the lines 150 provided on both sides of the light emission area EA of each of the subpixels SP.

Consequently, in the display apparatus 100 according to one embodiment of the present disclosure, the first line 151 and the third line 153 may be disposed to overlap the second area A2 of each of the first subpixel SP1 and the third subpixel SP3, which have relatively weak color visibility, and the second line 152 and the third line 153 may be disposed to overlap a portion of the light emission area EA and the first area A1 of each of the second subpixel SP2 and the fourth subpixel SP4, which have strong color visibility.

In the display apparatus 100 according to one embodiment of the present disclosure, the second line 152 and the third line 153 may have light reflectance of 90% or more. Since the second line 152 and the third line 153 overlap a portion of the light emission area EA and the first area A1 of each of the second subpixel SP2 and the fourth subpixel SP4, when the second line 152 and the third line 153 are provided as reflective lines having light reflectance of 90% or more, the second line 152 and the third line 153 may reflect light, which is directed toward the second line 152 and the third line 153, among the light emitted from the light emission area EA as shown in FIG. 6. Therefore, the display apparatus 100 according to one embodiment of the present disclosure may improve light extraction efficiency even through the second line 152 and the third line 153. The second line 152 and the third line 153 according to one example may include any one of silver (Ag), aluminum (Al) and their alloy, but the present disclosure is not limited thereto. The reflective line may include an upper surface in a direction facing the reflective portion 130, and the upper surface of the reflective line may be made of any one of silver (Ag), aluminum (Al) and their alloy.

Therefore, in the display apparatus 100 according to one embodiment of the present disclosure, as shown in FIG. 6, the light emitted from the light emission area EA and directed toward the line 150 (or the second line 152 and/or the third line 153) may be primarily reflected by the line 150 and may be secondarily reflected by the reflective portion 130. The light secondarily reflected by the reflective portion 130 may be thirdly reflected by a reflective electrode 117 of a light emitting element layer E included in the plurality of subpixels SP and then may be emitted to the light emission area EA or the non-light emission area NEA of the subpixel SP for emitting light. As a result, the display apparatus 100 according to one embodiment of the present disclosure may extract light even through the line disposed in the non-light emission area NEA, and thus overall light extraction efficiency may be improved.

When the line is not a line having reflectance of 90% or more, light may be reflected by the line but light intensity may be reduced. Therefore, in this case, a luminance deviation may be caused between the subpixels SP. In the display apparatus 100 according to one embodiment of the present disclosure, since the second line 152 and the third line 153, which overlap the first area A1 and a portion of the light emission area EA of each of the second subpixel SP2 and the fourth subpixel SP4, are provided as reflective lines having reflectance of 90% or more, a luminance deviation between the subpixels SP may not be generated.

Referring back to FIG. 4, the plurality of lines 150 may be disposed below the pattern portion 120. The plurality of lines 150 may be disposed in the non-light emission area NEA, for example, the first area A1 and/or the second area A2. The second area A2 according to one example may mean a predetermined area that overlaps a boundary portion (or a boundary line) between the plurality of subpixels SP. For example, as shown in FIG. 4, the second area A2 may mean an area having a width wider than that of the boundary portion (or the boundary line) of the plurality of subpixels SP while overlapping the boundary portion (or the boundary line). In the display apparatus 100 according to one embodiment of the present disclosure, the line disposed to overlap the first area A1 and a portion of the light emission area EA may be provided as a reflective line, so that light extraction efficiency may be improved.

The display apparatus 100 according to one embodiment of the present disclosure is provided with the reflective portion 130 on the pattern portion 120 between the plurality of subpixels SP, so that light, which is directed toward an adjacent subpixel SP, among light emitted from the light emission area EA, may be reflected toward the light emission area EA of the subpixel SP for emitting light and/or the non-light emission area NEA of the subpixel SP for emitting light. Therefore, the display apparatus 100 according to one embodiment of the present disclosure may improve light extraction efficiency of the subpixel SP for emitting light.

Since the pattern portion 120 according to one example is provided to surround the light emission area EA of each of the plurality of subpixels SP, the reflective portion 130 may be also provided to surround the light emission area EA of each of the plurality of subpixels SP. The light reflected by the reflective portion 130 may be emitted to the outside through a lower surface of the substrate 110 in the non-light emission area NEA spaced apart from the light emission area EA of the subpixel SP for emitting light and/or the light emission area EA of the subpixel SP for emitting light.

The pattern portion 120 according to one example may be formed to be concave near the non-light emission area NEA. For example, the pattern portion 120 may be formed to be concave in an overcoat layer 113 (shown in FIG. 4) on the substrate 110. As shown in FIG. 2, the pattern portion 120 may be provided to surround the light emission area EA. The pattern portion 120 may be disposed to be spaced apart from the light emission area EA. In FIG. 2, point hatching (or shading) is to indicate the bank. The pattern portion 120 according to one example may be provided to surround the light emission area EA in the form of a slit or a trench. For example, a width of the pattern portion 120 may be formed to be reduced from the reflective portion 130 toward the substrate 110. Also, as shown in FIG. 2, the pattern portion 120 may include an area exposed without being covered by the bank 115 (shown in FIG. 3). Therefore, the pattern portion 120 may be expressed as terms such as a groove, a slit, a trench, a bank slit and a bank trench.

The reflective portion 130 according to one example may be formed to be concave along a profile of the pattern portion 120 formed to be concave near the non-light emission area NEA, thereby being formed to be concave near the non-light emission area NEA. The reflective portion 130 may be made of a material capable of reflecting light, and may reflect light, which is emitted from the light emission area EA and directed toward the adjacent subpixel SP, toward the light emission area EA of the subpixel SP for emitting light. As shown in FIG. 4, since the reflective portion 130 is disposed to be inclined while surrounding the light emission area EA, the reflective portion 130 may be expressed as terms such as a side reflective portion or an inclined reflective portion. As shown in FIG. 4, the reflective portion 130 may include a flat surface 131 disposed in central part of the second area A2 and a curved surface 132 connected to the flat surface 131. The flat surface 131 may be disposed in parallel with the bottom surface 120b (shown in FIG. 4) of the pattern portion 120. The curved surface 132 may be formed in a rounded shape along a profile of the inclined surface 120s of the pattern portion 120. Most of the light toward the adjacent subpixel of the light emitted from the subpixel SP for emitting light may be reflected by the curved surface 132 and then emitted to the light emission area EA of the subpixel SP for emitting light or the non-light emission area NEA of the subpixel SP for emitting light.

Meanwhile, the display apparatus 100 according to one embodiment of the present disclosure may be implemented in a bottom emission type in which light emitted from the light emission area EA is emitted to the lower surface of the substrate 110. Therefore, in the display apparatus 100 according to one embodiment of the present disclosure, the light emitted to the lower surface of the substrate 110 may be the light in which direct light emitted from the light emission area EA and directly emitted to the lower surface of the substrate 110 and reflective light obtained by reflecting the light, which is emitted from the light emission area EA and directed toward the adjacent subpixel SP, by the reflective portion 130 and emitting the light to the lower surface of the substrate 110 are combined with each other. The reflective light may include reflective light that is wave-guided on an interface between a light emitting layer and an electrode and reflected by the reflective portion 130 and then emitted to the substrate 110. Therefore, the display apparatus 100 according to one embodiment of the present disclosure may more improve light extraction efficiency than the display apparatus in which the reflective portion 130 formed to be concave is not provided.

Hereinafter, reference to FIGS. 1 to 5, the display apparatus 100 according to an embodiment of the present specification will be described in more detail.

Referring to FIGS. 1 and 4, the display apparatus 100 according to one embodiment of the present disclosure may include a display panel having a gate driver GD, a light extraction portion 140 overlapping a light emission area EA, a source drive integrated circuit (hereinafter, referred to as “IC”) 160, a flexible film 170, a circuit board 180, and a timing controller 190.

The display panel may include a substrate 110 and an opposite substrate 200 (shown in FIG. 4).

The substrate 110 may include a thin film transistor, and may be a transistor array substrate, a lower substrate, a base substrate, or a first substrate. The substrate 110 may be a transparent glass substrate or a transparent plastic substrate. The substrate 110 may include a display area DA and a non-display area NDA. For example, the display area DA may be disposed in a central portion of the display panel. The display area DA may include a plurality of pixels P.

The opposite substrate 200 may encapsulate (or seal) the display area DA disposed on the substrate 110. For example, the opposite substrate 200 may be bonded to the substrate 110 via an adhesive member (or clear glue). The opposite substrate 200 may be an upper substrate, a second substrate, or an encapsulation substrate.

The gate driver GD supplies gate signals to the gate lines in accordance with the gate control signal input from the timing controller 190. The gate driver GD may be formed on one side of the display area DA or in the non-display area NDA outside both sides of the display area DA in a gate driver in panel (GIP) method, as shown in FIG. 1.

The non-display area NDA is an area on which an image is not displayed, and may be a peripheral area, a signal supply area, an inactive area or a bezel area. The non-display area NDA may be configured to be in the vicinity of the display area DA. That is, the non-display area NDA may be disposed to surround the display area DA.

A pad area PA may be disposed in the non-display area NDA. The pad area PA may supply a power source and/or a signal for outputting an image to the pixel P provided in the display area DA. Referring to FIG. 1, the pad area PA may be provided above the display area DA.

The source drive IC 160 receives digital video data and a source control signal from the timing controller 190. The source drive IC 160 converts the digital video data into analog data voltages in accordance with the source control signal and supplies the analog data voltages to the data lines. When the source drive IC 160 is manufactured as a driving chip, the source drive IC 160 may be packaged in the flexible film 170 in a chip on film (COF) method or a chip on plastic (COP) method.

Pads, such as data pads, may be formed in the non-display area NDA of the display panel. Lines connecting the pads with the source drive IC 160 and lines connecting the pads with lines of the circuit board 180 may be formed in the flexible film 170. The flexible film 170 may be attached onto the pads by using an anisotropic conducting film, whereby the pads may be connected with the lines of the flexible film 170.

The circuit board 180 may be attached to the flexible films 170. A plurality of circuits implemented as driving chips may be packaged in the circuit board 180. For example, the timing controller 190 may be packaged in the circuit board 180. The circuit board 180 may be a printed circuit board or a flexible printed circuit board.

The timing controller 190 receives the digital video data and a timing signal from an external system board through a cable of the circuit board 180. The timing controller 190 generates a gate control signal for controlling an operation timing of the gate driver GD and a source control signal for controlling the source drive ICs 160 based on the timing signal. The timing controller 190 supplies the gate control signal to the gate driver GD, and supplies the source control signal to the source drive ICs 160.

Referring to FIGS. 3 and 4, the substrate 110 according to an example may include the light emission area EA and the non-light emission area NEA.

The substrate 110 according to an example may include gate lines, data lines, pixel driving power lines, and a plurality of pixels P. Each of the plurality of pixels P may include a plurality of subpixels SP that may be defined by the gate lines and the data lines.

Each of the plurality of subpixels SP includes a thin film transistor and a light emitting element layer E connected to the thin film transistor. Each light emitting element layer E may include a light emitting layer (or an organic light emitting layer) interposed between the pixel electrode and the reflective electrode.

For each of the subpixels SP, a predetermined current is supplied to the organic light emitting element in accordance with a data voltage of the data line when a gate signal is input from the gate line by using the thin film transistor. For this reason, the light emitting layer of each of the subpixels may emit light with a predetermined brightness in accordance with the predetermined current.

The plurality of subpixels SP according to one example may be disposed to be adjacent to each other in the first direction (X-axis direction). The first direction (X-axis direction) may be a horizontal direction based on FIG. 2. The horizontal direction may be a direction in which a gate line GL, a sensing line SL and a fourth line 154 are disposed. The fourth line 154 may be a branch line connected to the third line 153 disposed in the second direction (Y-axis direction).

The second direction (Y-axis direction) may be a direction crossing the first direction (X-axis direction), and may be a vertical direction based on FIG. 2. The vertical direction may be a direction in which data lines including the first data line DL1, the second data line DL2, the third data line DL3 and the fourth data line DL4 are disposed. Alternatively, the vertical direction may be a direction in which the pixel power line EVDD and the reference line RL are disposed. The third direction (Z-axis direction) a direction crossing each of the first direction (X-axis direction) and the second direction (Y-axis direction), and may be a thickness direction of the display apparatus 100.

The plurality of subpixels SP may include a first subpixel SP1, a second subpixel SP2, a third subpixel SP3 and a fourth subpixel SP4 arranged adjacent to each other in the first direction (X-axis direction). For example, the first subpixel SP1 may be a red subpixel, the second subpixel SP2 may be a green subpixel, the third subpixel SP3 may be a blue subpixel and the fourth subpixel SP4 may be a white subpixel, but is not limited thereto. However, the arrangement order of the first subpixel SP1, the second subpixel SP2, the third subpixel SP3 and the fourth subpixel SP4 may be changed.

Each of the first to fourth subpixels SP1 to SP4 may include a light emission area EA and a circuit area CA. The light emission area EA may be disposed at one side (or an upper side) of a subpixel area, and the circuit area CA may be disposed at the other side (or a lower side) of the subpixel area. For example, in the second direction Y, the circuit area CA may be disposed at the lower side of the light emission area EA. The light emission areas EA of the first to fourth subpixels SP1 to SP4 may have different sizes (or areas).

The first to fourth subpixels SP1 to SP4 may be disposed to be adjacent to one another along the first direction (X-axis direction). For example, two data lines DL extended along the second direction (Y-axis direction) may be disposed in parallel with each other between the first subpixel SP1 and the second subpixel SP2 and between the third subpixel SP3 and the fourth subpixel SP4. A pixel power line EVDD extended along the first direction (X-axis direction) may be disposed between the light emission area EA and the circuit area CA of each of the first to fourth subpixels SP1 to SP4. The gate line GL and a sensing line SL extended along the first direction (X-axis direction) may be disposed below the circuit area CA. The pixel power line EVDD extended along the second direction (Y-axis direction) may be disposed at one side of the first subpixel SP1 or the fourth subpixel SP4. A reference line RL extended along the second direction (Y-axis direction) may be disposed between the second subpixel SP2 and the third subpixel SP3. The reference line RL may be used as a sensing line for sensing a change of characteristics of a driving thin film transistor and/or a change of characteristics of the light emitting element layer, which is disposed in the circuit area CA, from the outside in a sensing driving mode of the pixel P.

As described above, the first data line DL1 and the third data line DL3 may be included in the first line 151 having the first width W1. The second data line DL2 and the fourth data line DLA may be included in the second line 152 having the second width W2. The pixel power line EVDD and the reference line RL may be included in the third data line 153 having a third width W3.

The display apparatus 100 according to one embodiment of the present disclosure may be provided so that the first line 151 and the third line 153 are disposed in the first subpixel SP1 and the third subpixel SP3, which have relatively weak color visibility and the first line 151 and the third line 153 are disposed only in the second area A2 so as not to overlap the light emission area EA and the first area A1 of each of the first subpixel SP1 and the third subpixel SP3. Therefore, in the display apparatus 100 according to one embodiment of the present disclosure, the aperture ratio of the first subpixel SP1 and the third subpixel SP3 may be improved, and thus a color visibility deviation or a luminance deviation from the second subpixel SP2 and the fourth subpixel SP4 may be reduced.

In the display apparatus 100 according to one embodiment of the present disclosure, the second line 152 and the third line 153 may be disposed in the second subpixel SP2 and the fourth subpixel SP4, which have relatively strong color visibility, and the second line 152 and the third line 153 may be provided as reflective lines while being disposed to overlap a portion of the light emission area EA and the first area A1 of each of the the second subpixel SP2 and the fourth subpixel SP4. Therefore, in the display apparatus 100 according to one embodiment of the present disclosure, the aperture ratio of the second subpixel SP2 and the fourth subpixel SP4 to be smaller than that of the first subpixel SP1 and the third subpixel SP3 but light extraction may be additionally performed through the reflective lines.

In the display apparatus 100 according to one embodiment of the present disclosure, each of the plurality of subpixels SP may include the light extraction portion 140. The light extraction portion 140 may be formed on the overcoat layer 113 (shown in FIG. 4) to overlap the light emission area EA of the subpixel. The light extraction portion 140 may be formed on the overcoat layer 113 of the light emission area EA to have a curved (or uneven) shape, thereby changing a propagation path of light emitted from the light emitting element layer E to increase light extraction efficiency. For example, the light extraction portion 140 may be a non-flat portion, an uneven pattern portion, a micro lens portion, or a light scattering pattern portion.

The light extraction portion 140 may include a plurality of concave portions 141. The plurality of concave portions 141 may be formed to be concave inside the overcoat layer 113. For example, the plurality of concave portions 141 may be formed or configured to be concave from an upper surface 1131a of a first layer 1131 included in the overcoat layer 113. Therefore, the first layer 1131 may include a plurality of concave portions 141. The first layer 1131 may be disposed between the substrate 110 and the light emitting element layer E.

A second layer 1132 of the overcoat layer 113 may be disposed between the first layer 1131 and a light emitting element layer E (or a pixel electrode 114 shown in FIG. 4). The second layer 1132 according to one example may be formed to be wider than the pixel electrode 114 in a first direction (X-axis direction). Thus, a portion of the second layer 1132 may overlap the light emissive area EA, and the other portion of the second layer 1132 may be in contact with a portion of the bottom surface 120b while covering the inclined surface 120s of the pattern portion 120. That is, as shown in FIG. 4, the second layer 1132 may be extended from the light emission area EA to the first area A1 and thus may be in contact with a portion of the bottom surface 120b while covering the inclined surface 120s of the pattern portion 120. Since an upper surface 1132a of the second layer 1132 is provided flat, the pixel electrode 114 disposed on the upper surface 1132a of the second layer 1132 may also be provided flat.

Meanwhile, a refractive index of the second layer 1132 may be greater than that of the first layer 1131. Therefore, as shown in FIG. 4, a path of light emitted from a light emitting layer 116 and directed toward the substrate 110 may be changed toward the reflective portion 130 due to a difference in refractive indexes between the second layer 1132 and the first layer 1131 of the light extraction portion 140. Therefore, the light having a path formed toward the reflective portion 130 by the light extraction portion 140 may be reflected by the reflective portion 130 and emitted toward the light emission area EA of the subpixel SP for emitting light. Hereinafter, the light reflected by the reflective portion 130 and emitted toward the substrate 110 will be defined as the reflective light.

The reflective light according to one example may include first reflective light L1 (or WG mode extraction light L1 shown in FIG. 4) reflected from the reflective portion 130 and emitted to the substrate 110 after being subjected to optical waveguide through total reflection between the pixel electrode 114 and the reflective electrode 117, second reflective light L2 (shown in FIG. 4) reflected from the reflective portion 130 and emitted to the substrate 110 after its path is changed by the light extraction portion 140, and third reflective light L3 (or substrate mode extraction light) emitted from the light emitting layer 116, primarily reflected by the reflective portion 130, secondarily reflected on a boundary surface between the lower surface of the substrate 110 and the air layer, thirdly reflected by the reflective portion 130 and then emitted to the substrate 110. The first reflective light L1, the second reflective light L2 and the third reflective light L3, which are shown in solid lines in FIG. 4, may be the reflective light extracted by being reflected by the reflective portion 130.

In the display apparatus 100 according to one embodiment of the present disclosure, there may further be a light which is emitted to the substrate 110 through the light extraction portion 140 without being reflected by the reflective portion 130. For example, as shown in FIG. 4, in the display apparatus 100, there may be a primary extraction light LA emitted from the light emitting layer 116, refracted on a boundary surface between the plurality of concave portions 141 included in the light extraction portion 140 and the first layer 1131 and then emitted to the substrate 110, and recycle light L5 emitted from the light emitting layer 116, primarily refracted on the boundary surface between the plurality of concave portions 141 and the first layer 1131, secondarily reflected on the lower surface of the pixel electrode 114, refracted on the boundary surface between the plurality of concave portions 141 and the first layer 1131 and then emitted to the substrate 110. Therefore, the display apparatus 100 according to one embodiment of the present disclosure may improve the overall light extraction efficiency through the light extraction portion 140 and the reflective portion 130.

In addition, in the display apparatus 100 according to one embodiment of the present disclosure, there may further be a line reflective light L6 (shown in FIG. 6) emitted from the light emission area EA and sequentially reflected by the line 150, the reflective portion 130 and the reflective electrode 117 to be emitted to the substrate 110.

The first reflective light L1 and the third reflective light L3 according to one example may be emitted from the light emission area EA to the substrate 110. The second reflective light L2 may be emitted from a position spaced apart from the light emission area EA to the substrate 110. That is, the second reflective light L2 may be emitted from the non-light emission area NEA or the peripheral area to the substrate 110. The third reflective light L3, primarily extracted light L4, recycle light L5 and the line reflective light L6 may be emitted from the light emission area EA or the non-light emission area NEA to the substrate 110.

In case of a general display apparatus, since a pixel driving line for driving a pixel is disposed below the bank, a portion of the light emitted from the light emission area is covered by the pixel driving line and thus cannot be emitted to the substrate. However, in the display apparatus 100 according to one embodiment of the present disclosure, the second data line DL2 and the reference line RL (or the pixel power line EVDD), which are disposed to overlap the first area A1 and a portion of the light emission area EA, are formed of reflective lines, so that the light directed toward the second data line DL2 and/or the reference line RL (Or the pixel power line EVDD) may be reflected by the second data line DL2 and/or the reference line RL (or the pixel power line EVDD) and then emitted to the substrate 110 through the reflective portion 130 and the reflective electrode 117. Therefore, the display apparatus 100 according to one embodiment of the present disclosure may perform light extraction by using the reflective line, thereby maximizing light extraction efficiency of light that is emitted.

Meanwhile, as shown in FIG. 4, the second reflective light L2 may be emitted to the substrate 110 from the position spaced apart from the light emission area EA, but is not limited thereto. The first reflective light L1 may be emitted to the substrate 110 from the position spaced apart from the light emission area EA.

In the display apparatus 100 according to one embodiment of the present disclosure, since the pattern portion 120 is disposed to surround the light emission area EA, at least a portion of the reflective portion 130 on the pattern portion 120 may be disposed to surround the light emission area EA. Therefore, the reflective light may be emitted to the substrate 110 from the position spaced apart from the light emission area EA while surrounding at least a portion of the light emission area EA. As shown in the image of FIG. 5, it can be seen that the reflective light is emitted between the subpixels SP and from a corner portion of each subpixel SP. The corner portion may be an edge portion. In case of a general display apparatus, since the corner portion of the light emission area is bent at a predetermined angle, light emission efficiency may be reduced as compared with a central portion of the light emission area. In contrast, in the display apparatus 100 according to one embodiment of the present disclosure, since the reflective portion 130 is disposed in the non-light emission area surrounding the corner portion of the light emission area, even though the corner portion of the light emission area is bent at a predetermined angle, light extraction may be performed, whereby the overall light emission efficiency may be increased.

Meanwhile, since FIG. 5 is exemplary, the reflective light may be emitted from the position spaced apart from the light emission area EA while surrounding the entire light emission area EA. Therefore, in the display apparatus 100 according to one embodiment of the present disclosure, since light dissipated by optical waveguide and/or light dissipated by the interface total reflection may be emitted to the substrate from the non-light emission area NEA in the form of reflective light through the reflective portion 130 surrounding the light emission area EA, light extraction efficiency may be improved and the overall light emission efficiency may be increased.

Also, in the display apparatus 100 according to one embodiment of the present disclosure, since light, which cannot be emitted to the substrate by being covered by a line, may be emitted to the outside through the reflective line 150 overlapping the first area A1 and a part of the light emission area EA, light extraction efficiency may be maximized.

Hereinafter, a structure of each of the plurality of subpixels SP will be described in detail.

Referring to FIG. 4, the display apparatus 100 according to one embodiment of the present disclosure may further include a buffer layer BL, a circuit element layer, a thin film transistor (not shown), a pixel electrode 114, a bank 115, a light emitting layer 116, a reflective electrode 117, an encapsulation layer 118 and a color filter CF.

In more detail, each of the subpixels SP according to one embodiment may include a circuit element layer provided on an upper surface of a buffer layer BL, an overcoat layer 113 provided on the circuit element layer, a pixel electrode 114 provided on the overcoat layer 113, a bank 115 covering an edge of the pixel electrode 114, a light emitting layer 116 on the pixel electrode 114 and the bank 115, a reflective electrode 117 on the light emitting layer 116, and an encapsulation layer 118 on the reflective electrode 117, wherein the circuit element layer includes a gate insulating layer (not shown), an interlayer insulating layer 111 and a passivation layer 112.

The thin film transistor for driving the subpixel SP may be disposed on the circuit element layer. The pixel electrode 114, the light emitting layer 116 and the reflective electrode 117 may be included in the light emitting element layer E.

The buffer layer BL may be formed between the substrate 110 and the gate insulating layer to protect the thin film transistor. The buffer layer BL may be disposed on the entire surface (or front surface) of the substrate 110. The pixel power line EVDD for pixel driving may be disposed between the buffer layer BL and the passivation layer 112. The buffer layer BL may serve to block diffusion of a material contained in the substrate 110 into a transistor layer during a high temperature process of a manufacturing process of the thin film transistor.

The thin film transistor (or a drive transistor) according to an example may include an active layer, a gate electrode, a source electrode, and a drain electrode. The active layer may include a channel area, a drain area and a source area, which are formed in a thin film transistor area of a circuit area of the subpixel SP. The active layer may be formed of a semiconductor material.

The gate insulating layer may be formed on the channel area of the active layer. The interlayer insulating layer 111 may be formed to partially overlap the gate electrode and the drain area and source area of the active layer. As shown in FIG. 4, the interlayer insulating layer 111 may be formed over the entire subpixel SP.

The source electrode may be electrically connected to the source area of the active layer through a source contact hole provided in the interlayer insulating layer 111 overlapped with the source area of the active layer. The drain electrode may be electrically connected to the drain area of the active layer through a drain contact hole provided in the interlayer insulating layer 111 overlapped with the drain area of the active layer.

A passivation layer 112 may be provided on the substrate 110 to cover a pixel area. The passivation layer 112 covers a drain electrode, a source electrode and a gate electrode of a thin film transistor and a buffer layer BL. The plurality of lines 150 may be disposed between the passivation layer 112 and an interlayer insulating layer 111. For example, the plurality of lines 150 may include a first data line DL1 for driving the first subpixel SP1, a second data line DL2 for driving the second subpixel SP2, a third data line DL3 for driving the third subpixel SP3 and a fourth data line DLA for driving the fourth subpixel SP4. The plurality of lines 150 may further include a pixel power line EVDD and a reference line RL. The passivation layer 112 may be formed over the entire circuit area and the light emission area. This passivation layer 112 may be omitted. A color filter CF may be disposed on the passivation layer 112.

The overcoat layer 113 may be provided on the substrate 110 to cover the passivation layer 112 and the color filter CF. When the passivation layer 112 is omitted, the overcoat layer 113 may be provided on the substrate 110 to cover the circuit area. The overcoat layer 113 may be formed in the circuit area CA in which the thin film transistor is disposed and the light emission area EA. In addition, the overcoat layer 113 may be formed in the other non-display area NDA except a pad area PA of the non-display area NDA and the entire display area DA. Therefore, the overcoat layer 113 may have a size relatively wider than that of the display area DA.

The overcoat layer 113 according to one example may be formed to have a relatively thick thickness, thereby providing a flat surface on the display area DA and the non-display area NDA. For example, the overcoat layer 113 may be made of an organic material such as photo acryl, benzocyclobutene, polyimide and fluorine resin.

The overcoat layer 113 formed in the display area DA (or the light emission area EA) may include a plurality of concave portions 141. The plurality of concave portions 141 are the elements of the light extraction portion 140 for increasing light efficiency of the light emission area EA, and may be formed inside the overcoat layer 113. In detail, as shown in FIG. 3, the plurality of concave portions 141 may be formed in a concave shape on the first layer 1131 of the overcoat layer 113. The plurality of concave portions 141 are provided to be connected to each other so that an embossed shape may be formed in the first layer 1131.

The second layer 1132 having a refractive index higher than that of the first layer 1131 may be formed on the first layer 1131. A path of the light, which is directed toward the adjacent subpixel SP, among the light emitted from the light emitting element layer E may be changed toward the reflective portion 130 in accordance with a difference in the refractive index between the second layer 1132 and the first layer 1131. The second layer 1132 may be provided to cover the embossed shape of the first layer 1131 and thus the upper surface 1132a may be provided to be flat.

The pixel electrode 114 is formed on the upper surface 1132a of the second layer 1132 so that the pixel electrode 114 may be provided to be flat, and the light emitting layer 116 and the reflective electrode 117, which are formed on the pixel electrode 114, may be provided to be also flat. Since the pixel electrode 114, the light emitting layer 116, the reflective electrode 117, that is, the light emitting element layer E is provided to be flat in the light emission area EA, a thickness of each of the pixel electrode 114, the light emitting layer 116 and the reflective electrode 117 in the light emission area EA may be uniformly formed. Therefore, the light emitting layer 116 may uniformly emit light without deviation in the light emission area EA.

The plurality of concave portions 141 may be formed on the first layer 1131 through a photo process using a mask having an opening portion and then a patterning (or etching) or ashing process after the first layer 1131 is coated to cover the passivation layer 112 and the color filter CF. The plurality of concave portions 141 may be formed in an area overlapped with the color filter CF and/or an area that is not overlapped with the bank 115 of the non-light emission area NEA, but are not limited thereto. A portion of the plurality of concave portions 141 may be formed to overlap the bank 115.

Referring back to FIG. 3, the color filter CF disposed in the light emission area EA may be provided between the plurality of lines 150 and the pattern portion 120 or between the substrate 110 and the overcoat layer 113. Therefore, the color filter CF may be provided between the plurality of lines 150 and the reflective portion 130 or between the plurality of lines 150 and the pattern portion 120, for example, between the pixel power line EVDD and the reflective portion 130 or between the first data line DL1 and the pattern portion 120. The color filter CF may include a first color filter CF1 for converting white light emitted from the light emitting layer 116 into red light, a second color filter CF2 for converting white light into blue light, and a third color filter CF3 for converting white light into green light. The first color filter CF1 may be provided in the first subpixel SP1, the second color filter CF2 may be provided in the third subpixel SP3, and the third color filter CF3 may be provided in the fourth subpixel SP4. The second subpixel, which is a white subpixel, may not include a color filter because the light emitting layer 116 emits white light. As shown in FIG. 4, the color filter CF according to one example may be formed to be extended from the light emission area EA of each of the plurality of subpixels SP to the second area A2 by passing through the first area A1.

Meanwhile, as in a left portion of FIG. 4, in the display apparatus 100 according to one embodiment of the present disclosure, color filters having different colors may be provided to partially overlap each other in the boundary portion of the plurality of subpixels SP, for example, in the second area A2 between a first area A1 of a fourth subpixel SP4′ and the first area A1 of the first subpixel SP1 of adjacent pixels. In this case, in the display apparatus 100 according to one embodiment of the present disclosure, since light emitted from each subpixel SP may be prevented from being emitted to the adjacent subpixel SP due to the color filters overlapped with each other in the boundary portion of the subpixels SP, color mixture between the subpixels SP may be avoided. For example, as shown in FIG. 4, the first color filter CF1 and a third color filter CF3′ of the fourth subpixel SP4′, which is adjacent thereto, may overlap each other in the second area A2 overlapped with the boundary portion between the first subpixel SP1 and the fourth subpixel SP4′.

In a right portion of FIG. 4, that is, between the first subpixel SP1 and the second subpixel SP2, since the second subpixel SP2 is the white subpixel that does not include a color filter, only the first color filter CF1 may be formed to partially cover the second area A2 by passing through the first area A1 of the first subpixel SP1. In this case, the first color filter CF1 may partially overlap the first data line DL1 disposed in the second area A2. As shown in FIG. 4, the pixel power line EVDD disposed over the first area A1 and the second area A2 may overlap a third color filter CF3′ in the first area A1 of a fourth subpixel SP4′, and may overlap the first color filter CF1 and the third color filter CF3′ in the second area A2.

As shown in FIG. 4, the pixel power line EVDD (or the third line 153) and the first data line DL1 (or the first line 151) on both sides of the first subpixel SP1 may be disposed in the second area A2 on both sides of the first subpixel SP1. Therefore, in the first subpixel SP1, the width of the first opening area OPA1 defined by the pixel power line EVDD (or the third line 153) and the first data line DL1 (or the first line 151) may be wider than the width of the light emission area EA defined by the bank 115. Therefore, in the display apparatus 100 according to one embodiment of the present disclosure, since the pixel power line EVDD and the first data line DL1 do not interfere with emission of the light emitted from the light emission area EA of the first subpixel SP1, light extraction efficiency may be improved.

In addition, the first data line DL1 disposed in the second area A2 may not be provided as a reflective line. That is, the first data line DL1 may be provided as a non-reflective line. This is because that when the first data line DL1 is provided as a reflective line, a portion of the light emitted from the first subpixel SP1 may be reflected by the first data line DL1 and emitted toward the second subpixel SP2 to cause color mixture.

The first data line DL1 may be provided to at least partially overlap the first color filter CF1. When the first data line DL1 does not overlap the first color filter CF1, light leakage may occur between the first data line DL1 and the first color filter CF1. Therefore, in the display apparatus 100 according to one embodiment of the present disclosure, the first data line DL1 may be provided to partially overlap the first color filter CF1 in the second area A2 of the first subpixel SP1, and thus may be prevented from color mixture with the second subpixel SP2 without interfering with light extraction of the first subpixel SP1, and light leakage may be avoided when the first subpixel SP1 emits light.

Unlike the first data line DL1, the second data line DL2 may be disposed to overlap the first area A1 of the second subpixel SP2 and a portion of the light emission area EA. When the second data line DL2 is disposed to overlap the first area A1 of the second subpixel SP2 and a portion of the light emission area EA of the second subpixel SP, the light reflected by the reflective portion 130 of the second subpixel SP2 may be blocked (or interfered) by the second data line DL2 so that the light cannot be emitted to the outside. Therefore, in the display apparatus 100 according to one embodiment of the present disclosure, the second data line DL2 is provided as a reflective line having reflectance of 90% or more, so that the second data line DL2 may reflect light, whereby the light may be emitted toward the second subpixel SP2. Therefore, the second data line DL2 for driving the white subpixel SP2 may be disposed to overlap the first area A1 of the second subpixel SP2 and a portion of the light emission area EA of the second subpixel SP2.

Also, since the second data line DL2 is disposed to overlap the first area A1 of the second subpixel SP2 and a portion of the light emission area EA of the second subpixel SP2, the second data line DL2 may not overlap the color filter. This is because that the second subpixel SP2 does not include a color filter because the light emitting layer 116 emits white light.

Referring back to FIG. 4, the pixel electrode 114 of the subpixel SP may be formed on the overcoat layer 113. The pixel electrode 114 may be connected to the drain electrode or the source electrode of the thin film transistor through a contact hole passing through the overcoat layer 113 and the passivation layer 112. As shown in FIG. 3, the pixel electrode 114 may be provided to be narrower than the second layer 1132, but is not limited thereto. The pixel electrode 114 may be provided to be wider than the second layer 1132 in accordance with a cross-sectional position. For example, when the pixel electrode 114 is provided to be wider than the second layer 1132, an edge portion of the pixel electrode 114 may be connected to the drain electrode or the source electrode in the circuit area CA. In this case, the edge portion of the pixel electrode 114 may be covered by the bank 115. The pixel electrode 114 may be made of at least one of a transparent metal material or a semi-transmissive metal material.

Because the display apparatus 100 according to an embodiment of the present disclosure is configured as the bottom emission type, the pixel electrode 114 may be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag. Meanwhile, the material constituting the pixel electrode 114 may include MoTi. The pixel electrode 114 may be a first electrode or an anode electrode.

The bank 115 is an area from which light is not emitted, and may be provided to surround each of the light emitting portions (or concave portions 141 of the light extraction portion 140, shown in FIG. 4) of each of the plurality of subpixels SP. That is, the bank 115 may partition (or define) the concave portions 141 of each of the light emitting portion or the subpixels SP. The light emitting portion may mean a portion where the pixel electrode 114 and the reflective electrode 117 respectively are in contact with a lower surface and an upper surface of the light emitting layer 116 interposed therebetween.

The bank 115 may be formed to cover the edge of each pixel electrode 114 of each of the subpixels SP and expose a portion of each of the pixel electrodes 114. That is, the bank 115 may partially cover the pixel electrode 114. Therefore, the bank 115 may prevent the pixel electrode 114 and the reflective electrode 117 from being in contact with each other at the end of each pixel electrode 114. The exposed portion of the pixel electrode 114, which is not covered by the bank 115, may be included in the light emitting portion (or the light emission area). As shown in FIG. 4, the light emitting portion may be formed on the plurality of concave portions 141, and thus the light emitting portion (or the light emission area EA) may overlap the concave portions 141 in a thickness direction of the substrate 110.

The bank 115 according to one example may be disposed in the non-light emission area NEA of each of the plurality of subpixels SP as shown in FIG. 4. The bank 115 of each of the plurality of subpixels SP may be disposed in the first area A1. Therefore, as shown in FIG. 4, the banks 115 of the respective subpixels SP may be spaced apart from each other by the second area A2 (or bankless area) interposed therebetween, thereby the light emitting layer 116 and the reflective electrode 117 (or the reflective portion 130) may be disposed to be closer to the substrate 110 in the second area A2. In other words, the light emitting layer 116 and the reflective electrode 117 (or the reflective portion 130) may be disposed to be deeper toward the substrate 110 in the second area A2 than the first area A1 as the banks 115 of the respective subpixels SP are not formed in the second area A2. Therefore, since an area of a curved surface 132 of the reflective portion 130 may be increased, a reflective area for reflecting light toward an adjacent subpixel SP may be increased, so that light extraction efficiency may be improved.

After the bank 115 is formed, the light emitting layer 116 may be formed to cover the pixel electrode 114 and the bank 115. Therefore, the bank 115 may be provided between the pixel electrode 114 and the light emitting layer 116. The bank 115 may be expressed as the term of a pixel defining layer. The bank 115 according to one example may be made of an organic material or an inorganic material. The bank 115 may be formed to have the same or similar thickness along the profile of the pattern portion 120 (or the second layer 1132).

Referring again to FIG. 4, the light emitting layer 116 may be formed on the pixel electrode 114 and the bank 115. The light emitting layer 116 may be provided between the pixel electrode 114 and the reflective electrode 117. Thus, when a voltage is applied to each of the pixel electrode 114 and the reflective electrode 117, an electric field is formed between the pixel electrode 114 and the reflective electrode 117. Therefore, the light emitting layer 116 may emit light. The light emitting layer 116 may be formed in a plurality of subpixels SP and may have a common layer provided on the bank 115.

The light emitting layer 116 according to an embodiment may be provided to emit white light. The light emitting layer 116 may include a plurality of stacks which emit lights of different colors. For example, the light emitting layer 116 may include a first stack, a second stack, and a charge generating layer (CGL) provided between the first stack and the second stack. The light emitting layer may be provided to emit the white light, and thus, each of the plurality of subpixels SP may include a color filter CF suitable for a corresponding color.

The reflective electrode 117 may be formed on the light emitting layer 116. The reflective electrode 117 according to one example may include a metal material. The reflective electrode 117 may reflect the light emitted from the light emitting layer 116 in the plurality of subpixels SP toward the lower surface of the substrate 110. Therefore, the display apparatus 100 according to one embodiment of the present disclosure may be implemented as a bottom emission type display apparatus.

The display apparatus 100 according to one embodiment of the present disclosure is a bottom emission type and has to reflect light emitted from the light emitting layer 116 toward the substrate 110, and thus the reflective electrode 117 may be made of a metal material having high reflectance. The reflective electrode 117 according to one example may be formed of a metal material having high reflectance such as a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy may be an alloy such as silver (Ag), palladium (Pd) and copper (Cu). The reflective electrode 117 may be expressed as terms such as a second electrode, a cathode electrode and a counter electrode.

Meanwhile, in the display apparatus 100 according to one embodiment of the present disclosure, the reflective portion 130 may be a portion of the reflective electrode 117. Therefore, the reflective portion 130 may reflect light, which is directed toward the adjacent subpixel SP, toward the light emission area EA of the subpixel SP for emitting light. Since the reflective portion 130 is a portion of the reflection electrode 117, as shown in FIG. 4, the reflective portion 130 may be denoted by a reference numeral 117a. In the present disclosure, the reflective portion 130 may mean the reflective electrode 117 that overlaps the pattern portion 120 (or the first area A1 and the second area A2). In particular, the reflective portion 130 may mean the reflective electrode 117 formed of an inclined or curved surface while overlapping the pattern portion 120. Therefore, the reflective portion 130 may reflect the following light toward the light emission area EA and/or the non-emission area NEA of the subpixel SP for emitting light: light that is directed toward the adjacent subpixel SP, and/or light that is dissipated through total reflection between interfaces, and/or the light reflected on the line 150.

The encapsulation layer 118 is formed on the reflective electrode 117. The encapsulation layer 118 serves to prevent oxygen or moisture from being permeated into the light emitting layer 116 and the reflective electrode 117. To this end, the encapsulation layer 118 may include at least one inorganic film and at least one organic film. Meanwhile, as shown in FIG. 3, the encapsulation layer 118 may be disposed not only in the light emission area EA but also in the non-light emission area NEA. The encapsulation layer 118 may be disposed between the reflective electrode 117 and an opposing substrate 200.

Hereinafter, the pattern portion 120 and the reflective portion 130 of the display apparatus 100 according to one embodiment of the present disclosure will be described in more detail with reference to FIGS. 1 to 7.

In the display apparatus 100 according to one embodiment of the present disclosure, the pattern portion 120 may be provided near the light emission area EA (or near the non-light emission area NEA) and the reflective portion 130 may be provided on the pattern portion 120 in order to prevent light extraction efficiency from being reduced as some of the light emitted from the light emitting element layer is not discharged to the outside due to a disconnection of line and/or total reflection on an interface between the light emitting layer and the electrode and/or an interface between the substrate and the air layer.

For example, as shown in FIG. 4, the pattern portion 120 may be formed to be concave in the first layer 1131 of the overcoat layer 113. As shown in FIG. 4, the pattern portion 120 may be disposed near the non-light emission area NEA or the light emission area EA. That is, the pattern portion 120 may be disposed to surround the light emission area EA while being adjacent to the light extraction portion 140. The pattern portion 120 may be formed in the non-light emission area NEA together with the plurality of concave portions 141 when the plurality of concave portions 141 are formed in the light emission area EA. The pattern portion 120 may include a bottom surface 120b and an inclined surface 120s.

The bottom surface 120b of a pattern portion 120 according to one example may be extended from the inclined surface 120s formed in the first area A1 and formed to reach the second area A2. The bottom surface 120b of the pattern portion 120 is a surface formed closest to the substrate 110 in the pattern portion 120, and may be disposed to be closer to the substrate 110 (or the upper surface of the substrate) than the pixel electrode 114 (or the lower surface of the pixel electrode 114) in the light emission area EA. Therefore, as shown in FIG. 4, the bottom surface 120b of the pattern portion 120 may be provided at a depth equal to or similar to that of each of the plurality of concave portions 141. However, when the depth of the pattern portion 120 is lower than that of the concave portion 141, the area of the reflective portion 130 is reduced, whereby light extraction efficiency may be reduced. Therefore, in the display apparatus 100 according to one embodiment of the present disclosure, the depth of the pattern portion 120 may be equal to or deeper than that of the concave portion 141.

The inclined surface 120s of the pattern portion 120 may be formed in the first area A1 and disposed between the bottom surface 120b and the light extraction portion 140 in the first direction (X-axis direction). Therefore, the inclined surface 120s of the pattern portion 120 may be provided to surround the light emission area EA or the plurality of concave portions 141. As shown in FIG. 4, the inclined surface 120s may be connected to the bottom surface 120b. The inclined surface 120s may form a predetermined angle with the bottom surface 120b. For example, the angle formed by the inclined surface 120s and the bottom surface 120b may be an obtuse angle. Therefore, a width of the pattern portion 120 may be gradually reduced in a direction (or the third direction (Z-axis direction)) toward the substrate 110 from an opposing substrate 200 (or the reflective portion 130). As the obtuse angle is formed between the inclined surface 120s and the bottom surface 120b, the second layer 1132, the bank 115 and the reflective portion 130 (or the light emitting element layer E including the reflective portion 130) formed in a subsequent process may be formed to be concave along the profile of the pattern portion 120. Therefore, the light emitting element layer E may be formed to be concave in the pattern portion 120 formed to be concave in the non-light emission area NEA (or the peripheral area). The light emitting element layer E formed to be concave in the pattern portion 120 may mean that at least one of the pixel electrode 114, the light emitting layer 116 or the reflective electrode 117 is included therein.

As shown in FIG. 3, the pattern portion 120 may be provided to surround the light emission area EA. As the pattern portion 120 is provided to surround the light emission area EA, at least a portion of the reflective portion 130 disposed on the pattern portion 120 may be provided to surround the light emission area EA. Therefore, in the display apparatus 100 according to one embodiment of the present disclosure, since light may be extracted even from the non-light emission area NEA near the light emission area EA, overall light efficiency may be improved. Therefore, the display apparatus 100 according to one embodiment of the present disclosure may have the same light emission efficiency or more improved light emission efficiency even with low power as compared with a general display apparatus having no pattern portion 120 and reflective portion 130, whereby overall power consumption may be reduced.

In addition, the display apparatus 100 according to one embodiment of the present disclosure may allow the light emitting element layer E to emit light even with low power, thereby improving lifespan of the light emitting element layer E.

Referring back to FIG. 2, the pattern portion 120 may include a first pattern line 121 disposed in the first direction (X-axis direction) between the circuit area CA and the light emission area EA and a second pattern line 122 disposed in the second direction (Y-axis direction) crossing the first direction (X-axis direction). Referring to FIG. 2, the first pattern line 121 may mean the pattern portion 120 disposed in a horizontal direction, and the second pattern line 122 may mean the pattern portion 120 disposed in a vertical direction.

The first pattern line 121 may include a bottom surface and an inclined surface. The second pattern line 122 may include a bottom surface and an inclined surface. Since each of the bottom surface and the inclined surface of the first pattern line 121 and each of the bottom surface and the inclined surface of the second pattern line 122 are the same as each of the bottom surface 120b and the inclined surface 120s of the pattern portion 120, their description thereof is omitted. The first pattern line 121 and the second pattern line 122 may be connected to each other in the non-light emission area NEA (or the peripheral area) to surround the light emission area EA. The first pattern line 121 may be disposed between the subpixels SP for emitting light of the same color. The second pattern line 122 may be disposed between the subpixels SP for emitting light of different colors.

Since the second pattern line 122 is disposed between the subpixels SP for emitting light of different colors, the reflective portion 130 on the second pattern line 122 may prevent light of different colors from being emitted to other adjacent subpixels SP. Therefore, the display apparatus 100 according to the present disclosure may prevent color mixture (or color distortion) between the subpixels SP for emitting light of different colors, thereby improving color purity.

The second layer 1132 of the overcoat layer 113 may be further extended from the light emission area EA to the non-light emission area NEA to partially cover the inclined surface 120s of the pattern portion 120. That is, a portion of the second layer 1132 may extend from the light emission area EA to the first area A1 to cover the inclined surface 120s of the pattern portion 120. Therefore, as shown in FIG. 4, an end 1132c of the second layer 1132 may be in contact with the bottom surface 120b of the pattern portion 120. In this case, the end 1132c of the second layer 1132 may be in contact with only a portion of the bottom surface 120b. When the second layer 1132 entirely covers the bottom surface 120b, the depth of the reflective portion 130 formed on the pattern portion 120 may be relatively lowered, thereby reducing reflective efficiency. Therefore, in the display apparatus 100 according to one embodiment of the present disclosure, the second layer 1132 is provided to be in contact with only a portion of the bottom surface 120b without entirely covering the bottom surface 120b of the pattern portion 120 and thus the reflective portion 130 formed in a subsequent process may be formed to be close to the bottom surface 120b, whereby reflective efficiency may be improved.

As shown in FIG. 4, the bank 115 may be extended to cover the inclined surface 1132b of the second layer 1132 covering the inclined surface 120s of the pattern portion 120 while covering the edge of the pixel electrode 114. Therefore, the bank 115 may be in contact with a portion of the bottom surface 120b of the pattern portion 120, which is not covered by the second layer 1132. When the bank 115 entirely covers the bottom surface 120b, the depth of the reflective portion 130 formed on the pattern portion 120 is lowered, whereby reflective efficiency may be reduced. Therefore, as shown in FIG. 4, each of the second layer 1132 and the bank 115 on the bottom surface 120b of the pattern portion 120 may be discontinuously provided. That is, each of the second layer 1132 and the bank 115 may be disconnected on the bottom surface 120b of the pattern portion 120. As a result, in the display apparatus 100 according to one embodiment of the present disclosure, the bank 115 is provided to be in contact with only a portion of the bottom surface 120b without entirely covering the bottom surface 120b, so that the reflective portion 130 formed in a subsequent process may be formed to be close to the bottom surface 120b, whereby reflective efficiency may be improved.

As the bank 115 is provided to be in contact with only a portion of the bottom surface 120b of the pattern portion 120, as shown in FIG. 4, the bank 115 may be disconnected from the pattern portion 120 (or in the second area A2). As the bank 115 is disconnected from the pattern portion 120 (or in the second area A2), the reflective portion 130 may be disposed to be close to the bottom surface of the pattern portion 120. Therefore, the reflective portion 130 may be formed as deep as possible in the pattern portion 120 as compared with the case that the bank is not disconnected from the pattern portion, whereby reflective efficiency may be improved. In particular, since the pattern portion 120 includes a second pattern line 122 disposed between subpixels SP for emitting light of different colors, prevention of color mixture or color distortion may be maximized between the subpixels SP for emitting light of different colors. As shown in FIG. 4, since the pattern portion 120 (or the second pattern line 122) is disposed between the subpixels for emitting light of different colors, the second layer 1132, the bank 115, the light emitting layer 116 and the reflective portion 130 (or the reflective electrode 117) may be provided symmetrically based on the center of the pattern portion 120 (or the second pattern line 122).

The first pattern line 121 may be disposed between the subpixels SP for emitting light of the same color. Therefore, the second layer 1132 may be formed only to the first area A1 adjacent to the light emission area EA, and the second layer 1132 may not be formed on an opposite side of the light emission area EA based on the first pattern line 121. As a result, since the first pattern line 121 is disposed between the subpixels SP for emitting light of the same color, the bank 115, the light emitting layer 116 and the reflective portion 130 (or the reflective electrode 117) may be provided to be asymmetrical based on the center of the pattern portion 120 (or the first pattern line 121).

FIG. 5 is an image illustrating light extraction characteristics of a non-light emission area of a display apparatus 100 according to one embodiment of the present disclosure, and shows a state that all of four subpixels SP emit light. Among the light emitted from the light emission area EA, the light that is directed toward an adjacent subpixel SP through total reflection between the interfaces or directed toward the adjacent subpixel SP due to its path changed by the light extraction portion and/or the light reflected by the line 150 and directed toward the adjacent subpixel SP may be reflected in the reflective portion 130 formed to be concave on the pattern portion 120. Therefore, as shown in FIG. 5, at least some of the reflective light reflected by the reflective portion 130 may be emitted from the position spaced apart from the light emission area EA while surrounding the light emission area EA of each of the subpixels SP. Therefore, in the display apparatus 100 according to one embodiment of the present disclosure, since light dissipated by optical waveguide, light dissipated by the interface total reflection, and light that is blocked by line and extinguished may be emitted from the non-light emission area NEA in the form of reflective light through the reflective portion 130 surrounding at least a portion of the light emission area EA, light extraction efficiency may be improved and the overall light emission efficiency may be increased.

Also, since light may be extracted even from the non-light emission area NEA due to the reflective portion 130 provided in the non-light emission area NEA, the display apparatus 100 according to one embodiment of the present disclosure may have the same light emission efficiency or more improved light emission efficiency even with low power as compared with a general display apparatus having no reflective portion, whereby overall power consumption may be reduced.

Hereinafter, a structure of each of the first to fourth subpixels SP1, SP2, SP3 and SP4 will be described in detail with reference to FIGS. 4 to 10.

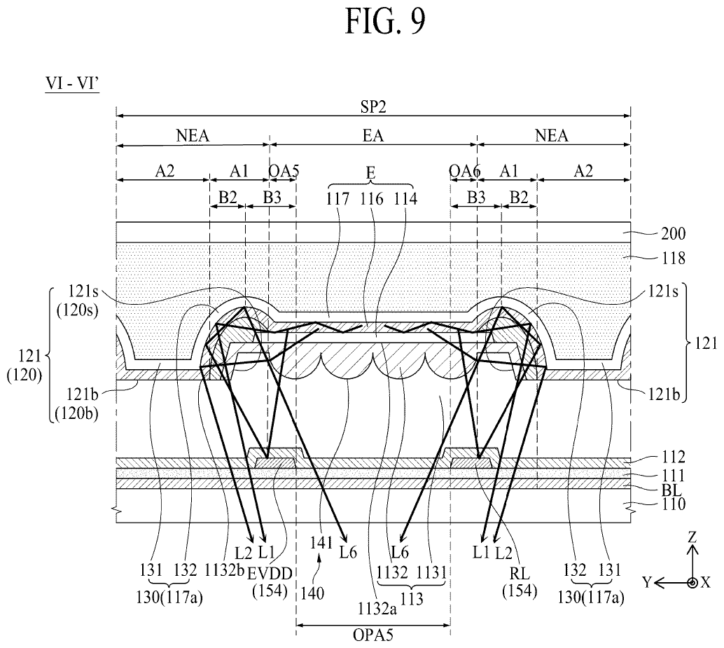

FIG. 6 is schematic cross-sectional view taken along line III-III′ shown in FIG. 2, FIG. 7 is a schematic cross-sectional view taken along line IV-IV′ shown in FIG. 2, FIG. 8 is a schematic cross-sectional view taken along line V-V′ shown in FIG. 2, and FIG. 9 is a schematic cross-sectional view taken along line VI-VI′ shown in FIG. 2.

FIG. 4 shows a cross section of a first subpixel SP1 in a first direction (X-axis direction), FIG. 6 shows a cross-section of a second subpixel SP2 in a first direction (X-axis direction), FIG. 8 shows a cross-section of a fourth subpixel SP4 in a first direction (X-axis direction), and FIG. 9 shows a cross-section of a second subpixel SP2 in a second direction (Y-axis direction).

Referring to FIG. 4, the display apparatus 100 according to one embodiment of the present disclosure may further include an opening area OPA in which the plurality of subpixels SP are partitioned by the plurality of lines. The opening area OPA may overlap the light emission area, and may refer to an area between the plurality of lines 150.

In the display apparatus 100 according to one embodiment of the present disclosure, one of the plurality of subpixels SP may be provided so that the width of the opening area OPA is wider than that of the light emission area EA. Also, in the display apparatus 100 according to one embodiment of the present disclosure, another one of the plurality of subpixels SP may be provided so that the width of the opening area OPA may be narrower than that of the light emission area EA. The one subpixel SP may be disposed to be adjacent to the another subpixel SP. Therefore, the display apparatus 100 according to one embodiment of the present disclosure may have a structure in which a subpixel SP having an opening area OPA of a wide width and a subpixel SP having an opening area OPA of a narrow width are alternately disposed. The display apparatus necessarily includes a line having a wide width such as the pixel power line EVDD involved in all of the first to fourth subpixels SP1, SP2, SP3 and SP4. When the wide line overlaps the light emission area EA of each of the subpixels SP, light emission efficiency may be reduced. Therefore, the display apparatus 100 according to one embodiment of the present disclosure is provided so that the line 150 partially overlaps only the light emission area EA of the subpixel SP having strong color visibility (or luminance), thereby reducing a luminance deviation between the subpixels SP. One subpixel SP provided so that the width of the opening area OPA is wider than that of the light emission area EA may be the first subpixel SP1 and/or the third subpixel SP3. Another subpixel SP provided so that the width of the opening area OPA is narrower than that of the light emission area EA may be the second subpixel SP2 and/or the fourth subpixel SP4.

In detail, as shown in FIG. 4, the pixel power line EVDD and the first and second data lines DL1 and DL2 may be disposed in the non-light emission area NEA without covering the light emission area EA of the first subpixel SP1. For example, the pixel power line EVDD may be disposed in the second area A2 positioned at a left side of the first subpixel SP1 without overlapping the first area A1 of a left side of the first subpixel SP1, and the first data line DL1 may be disposed in the second area A2 positioned at a right side of the first subpixel SP1 without overlapping the first area A1 of a right side of the first subpixel SP1. Therefore, the first subpixel SP1 may include the first opening area OPA1 between the first data line DL1 and the pixel power line EVDD. As shown in FIG. 4, the width of the first opening area OPA1 may be wider than that of the light emission area EA of the first subpixel SP1. Therefore, the display apparatus 100 according to one embodiment of the present disclosure may maximize light extraction through the reflective portion 130 and the light extraction portion 140 by reducing or minimizing arrangement of lines in a light extraction path.

Referring to FIG. 4, in the first subpixel SP1, since the pixel power line EVDD (or the third line 153) and the first data line DL1 (or the first line 151) do not overlap the light emission area EA (or the first area A1) of the first subpixel SP1, the third line 153 and the first line 151 at both sides based on the light emission area EA have their respective widths different from each other but may form a symmetric shape. Therefore, the display apparatus 100 according to one embodiment of the present disclosure may reduce a viewing angle deviation in the first direction (X-axis direction) (or left and right direction). As a result, the display apparatus 100 according to one embodiment of the present disclosure may maintain a luminance retention rate and a color retention rate in the left and right direction at the same level.

Referring to FIG. 6, the second data line DL2 and the reference line RL may be disposed to overlap the first area A1 of the second subpixel SP2 and a portion of the light emission area EA of the second subpixel SP2. For example, the second data line DL2 may be disposed to be extended to a portion of a left side of the light emission area EA while overlapping the first area A1 of a left side of the second subpixel SP2, and the reference line RL may be disposed to be extended to the first area A1 of a right side of the second subpixel SP2 and a portion of a right side of the light emission area EA while overlapping the second area A2 positioned at a right side of the second subpixel SP2. Therefore, the second subpixel SP2 may include the second opening area OPA2 between the second data line DL2 and the reference line RL. As shown in FIG. 6, the width of the second opening area OPA2 may be narrower than that of the light emission area EA of the second subpixel SP2. The width of the first opening area OPA1 of the first subpixel SP1 may be greater than that of the second opening area OPA2 of the second subpixel SP2. Therefore, the display apparatus 100 according to one embodiment of the present disclosure may reduce a color visibility deviation (or luminance deviation) between the first subpixel SP1 and the second subpixel SP2.

Since the second subpixel SP2 is a white subpixel, the second color filter CF2 of the third subpixel SP3 may be disposed up to the second area A2 positioned between the first area A1 of the second subpixel SP2 and the first area A1 of the third subpixel SP3 to overlap a part of the reference line RL, as shown in FIG. 6. Therefore, color mixture between the second subpixel SP2 and the third subpixel SP3 may be avoided.

Referring back to FIG. 6, in the second subpixel SP2, a first length OA1 of the second data line DL2 (or the second line 152) that overlaps the light emission area EA of the second subpixel SP2 may be the same as a second length OA2 of the reference line RL (or the third line 153) that overlaps the light emission area EA of the second subpixel SP2. Since the first length OA1 and the second length OA2 are the same as each other, the second line 152 and the third line 153 at both sides based on the light emission area EA have their respective widths different from each other but may form a symmetric shape. Therefore, the display apparatus 100 according to one embodiment of the present disclosure may reduce a viewing angle deviation in the first direction (X-axis direction) (or left and right direction). As a result, the display apparatus 100 according to one embodiment of the present disclosure may maintain a luminance retention rate and a color retention rate in the left and right direction at the same level.

Referring to FIG. 7, the reference line RL and the third data line DL3 may be disposed in the non-light emission area NEA without covering the light emission area EA of the third subpixel SP3. For example, the reference line RL may be disposed in the second area A2 positioned at a left side of the third subpixel SP3 without overlapping the first area A1 of a left side of the third subpixel SP3, and the third data line DL3 may be disposed in the second area A2 positioned at a right side of the third subpixel SP3 without overlapping the first area A1 of a right side of the third subpixel SP3. Therefore, the third subpixel SP3 may include the third opening area OPA3 between the third data line DL3 and the reference line RL. As shown in FIG. 7, the width of the third opening area OPA3 may be wider than that of the light emission area EA of the third subpixel SP3. Therefore, the display apparatus 100 according to one embodiment of the present disclosure may maximize light extraction through the reflective portion 130 and the light extraction portion 140 by reducing or minimizing arrangement of lines in a light extraction path.

In the third subpixel SP3, since the reference line RL (or the third line 153) and the third data line DL3 (or the first line 151) do not overlap the light emission area EA (or the first area A1) of the third subpixel SP3, the third line 153 and the first line 151 at both sides based on the light emission area EA have their respective widths different from each other but may form a symmetric shape. Therefore, the display apparatus 100 according to one embodiment of the present disclosure may reduce a viewing angle deviation in the first direction (X-axis direction) (or left and right direction), and may maintain a luminance retention rate and a color retention rate in the left and right direction at the same level.

Since the third subpixel SP3 is a blue subpixel, the second color filter CF2 of the third subpixel SP3 may be disposed up to the second area A2 positioned between the first area A1 of the fourth subpixel SP4 and the first area A1 of the third subpixel SP3 to overlap at least a portion of the third data line DL3. The third color filter CF3 of the fourth subpixel SP4 may be also disposed up to the second area A2 to overlap the second color filter CF2 on the third data line DL3, as shown in FIG. 7. Therefore, color mixture between the third subpixel SP3 and the fourth subpixel SP4 may be avoided.

Referring to FIG. 8, the fourth data line DL4 and the pixel power line EVDD may be disposed to overlap the first area A1 of the fourth subpixel SP4 and a portion of the light emission area EA of the fourth subpixel SP4. For example, the fourth data line DL4 may be disposed to be extended to a portion of the left side of the light emission area EA while overlapping the first area A1 of a left side of the fourth subpixel SP4, and the pixel power line EVDD may be disposed to be extended to the first area A1 of a right side of the fourth subpixel SP4 and a portion of a right side of the light emission area EA while overlapping the second area A2 positioned at a right side of the fourth subpixel SP4. Therefore, the fourth subpixel SP4 may include the fourth opening area OPA4 between the fourth data line DLA and the pixel power line EVDD. As shown in FIG. 8, the width of the fourth opening area OPA4 may be narrower than that of the light emission area EA of the fourth subpixel SP4. The width of the third opening area OPA3 of the third subpixel SP3 may be greater than that of the fourth opening area OPA4 of the fourth subpixel SP4. Therefore, the display apparatus 100 according to one embodiment of the present disclosure may reduce a color visibility deviation (or luminance deviation) between the third subpixel SP3 and the fourth subpixel SP4.

Consequently, the display apparatus 100 according to one embodiment of the present disclosure may be provided so that the width of the first opening area OPA1 of the first subpixel SP1 is the same as that of the third opening area OPA3 of the third subpixel SP3 and the width of the second opening area OPA2 of the second subpixel SP2 is the same as that of the fourth opening area OPA4 of the fourth subpixel SP4, but the present disclosure is not limited thereto. In accordance with the luminance deviation between the subpixels SP, the width of the first opening area OPA1 may be different from that of the third opening area OPA3 of the third subpixel SP3 and the width of the second opening area OPA2 of the second subpixel SP2 may be different from that of the fourth opening area OPA4 of the fourth subpixel SP4. In this case, a width of an opening area of a subpixel SP having relatively weak color visibility may be greater than that of an opening area of a subpixel SP having relatively strong color visibility.

Since the fourth subpixel SP4 is a green subpixel, the third color filter CF3 of the fourth subpixel SP4 may be disposed up to the second area A2 positioned between the first area A1 of the third subpixel SP3 and the first area A1 of the fourth subpixel SP4 to overlap at least a portion of the third data line DL3 and the second color filter CF2. Therefore, color mixture between the third subpixel SP3 and the fourth subpixel SP4 may be avoided. The third color filter CF3 of the fourth subpixel SP4 may be disposed up to the second area A2 positioned between a first area A1 of a first subpixel SP1″ of another pixel adjacent to the fourth subpixel SP4 and the first area A1 of the fourth subpixel SP4 to overlap a portion of the pixel power line EVDD and a first color filter CF1″ of the first subpixel SP1″, as shown in FIG. 8. Therefore, color mixture between the fourth subpixel SP4 and the first subpixel SP1″ of the pixel adjacent to the fourth subpixel SP4 may be avoided.

Referring back to FIG. 8, in the fourth subpixel SP4, a third length OA3 of the fourth data line DL4 (or the second line 152) that overlaps the light emission area EA of the fourth subpixel SP4 may be the same as a fourth length OA4 of the pixel power line EVDD (or the third line 153) that overlaps the light emission area EA of the fourth subpixel SP4. Since the third length OA3 and the fourth length OA4 are the same as each other, the second line 152 and the third line 153 at both sides based on the light emission area EA have their respective widths different from each other but may form a symmetric shape. Therefore, the display apparatus 100 according to one embodiment of the present disclosure may reduce a viewing angle deviation in the first direction (X-axis direction) (or left and right direction), and may maintain a luminance retention rate and a color retention rate in the left and right direction at the same level.

Referring to FIG. 9, the plurality of fourth lines 154 may be disposed to overlap the first area A1 of the second subpixel SP2 and a portion of the light emission area EA of the second subpixel SP2. For example, the fourth line 154 may be a line disposed in a direction crossing the first line 151, that is, in the first direction (X-axis direction). The fourth line 154 may be a branch line connected to the third line 153 (or the pixel power line EVDD and the reference line RL) disposed in the second direction (Y-axis direction).

The pixel power line EVDD may be disposed to be extended to a portion of a lower side of the light emission area EA while overlapping the first area A1 of a lower side of the second subpixel SP2, and the reference line RL may be disposed to be extended to a portion of an upper side of the light emission area EA while overlapping a portion of the first area A1 of an upper side of the second subpixel SP2. Therefore, the second subpixel SP2 may include a fifth opening area OPA5 between the pixel power line EVDD and the reference line RL. As shown in FIG. 9, a width of the fifth opening area OPA5 may be narrower than that of the light emission area EA of the second subpixel SP2 in the second direction (Y-axis direction). Therefore, the display apparatus 100 according to one embodiment of the present disclosure may reduce a color visibility deviation (or luminance deviation) between the third subpixel SP3 and the fourth subpixel SP4.

Meanwhile, since the second subpixel SP2 is a white subpixel, the color filter may not be disposed in the first area A1, the second area A2 and the light emission area EA of the second subpixel SP2.

Referring to FIG. 9, the fourth lines 154 are disposed to overlap a portion of the first area A1 of the second subpixel SP2 and a portion of the light emission area EA. Therefore, in the display apparatus 100 according to FIG. 9, the fourth line 154 is provided as a reflective line having reflectance of 90% or more, so that the fourth line 154 may reflect light, which is directed toward the fourth line 154, whereby the light may be emitted as line reflective light L6. Therefore, the display apparatus 100 according to one embodiment of the present disclosure may improve light extraction efficiency due to the line reflective light L6.

Referring back to FIG. 9, in the second subpixel SP2, a fifth length OA5 of the pixel power line EVDD (or the fourth line 154) that overlaps the light emission area EA of the second subpixel SP2 may be the same as a sixth length OA6 of the reference line RL (or the fourth line 154) that overlaps the light emission area EA of the second subpixel SP2. Since the fifth length OA5 and the sixth length OA6 are the same as each other, the fourth lines 154 at upper and lower sides based on the light emission area EA may form a symmetric shape. Therefore, the display apparatus 100 according to one embodiment of the present disclosure may reduce a viewing angle deviation in the second direction (Y-axis direction) (or up and down direction), and may maintain a luminance retention rate and a color retention rate in the up and down direction at the same level.

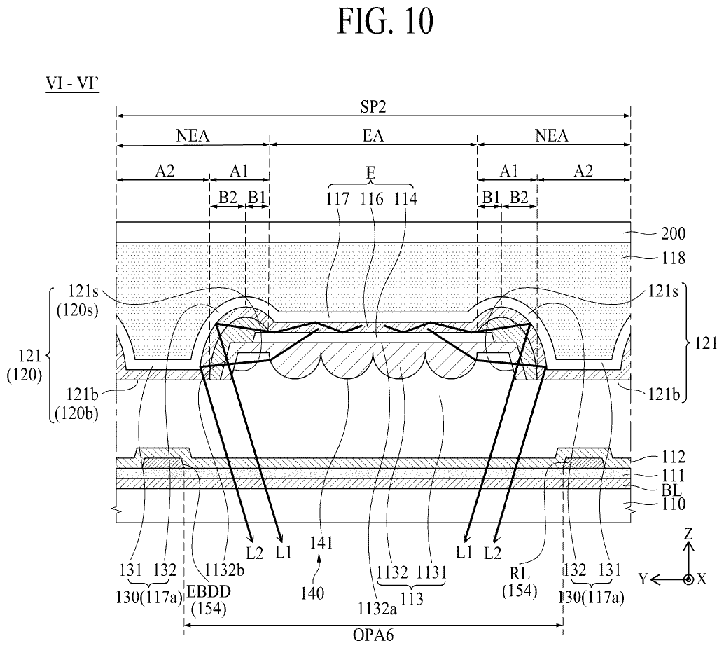

FIG. 10 is a schematic modified example taken along line VI-VI′ shown in FIG. 2.

FIG. 10 shows a cross-section of a second subpixel SP2 in a second direction (Y-axis direction), and is a modified example of FIG. 9.

In FIG. 9, the fourth lines 154 are disposed to overlap a portion of the first area A1 of the second subpixel SP2 and a portion of the light emission area EA. Therefore, in case of the display apparatus according to FIG. 9, the fourth line 154 is provided as a reflective line having reflectance of 90% or more, thereby reflecting light, which is directed toward the fourth line 154, to improve light extraction efficiency.

On the contrary, in case of the display apparatus according to FIG. 10, the fourth lines 154 (or the pixel power line EVDD and the reference line RL) may be disposed to overlap only the second area A2 of the second subpixel SP2. Therefore, in the display apparatus 100 according to FIG. 10, the fourth lines 154 may be disposed in the non-light emission area NEA without covering the light emission area EA of the second subpixel SP2. Therefore, in the display apparatus 100 according to FIG. 10, the second subpixel SP2 may include a sixth opening area OPA6 between the pixel power line EVDD and the reference line RL. As shown in FIG. 10, a width of the sixth opening area OPA6 may be wider than that of the light emission area EA of the second subpixel SP2 in the second direction (Y-axis direction). Therefore, the display apparatus 100 according to FIG. 10 may maximize light extraction through the reflective portion 130 and the light extraction portion 140 by reducing or minimizing the arrangement of the line on the light extraction path.

In the second subpixel SP2, since the pixel power line EVDD (or the fourth line 154) and the reference line RL (or the fourth line 154) do not overlap the light emission area EA (or the first area A1) of the second subpixel SP2, the fourth lines 154 of the upper and lower sides based on the light emission area EA may form a symmetric form. Therefore, the display apparatus 100 according to one embodiment of the present disclosure may reduce a viewing angle deviation of the second subpixel SP2 in the second direction (Y-axis direction) (or the up and down direction), and may maintain the luminance retention rate and the color retention rate in the up and down direction at the same level.

Although the fourth lines 154 disposed in the second subpixel SP2 have been described above, this structure may be equally applied to the first subpixel SP1, the third subpixel SP3 and the fourth subpixel SP4. Therefore, in each of the first subpixel SP1, the third subpixel SP3 and the fourth subpixel SP4, a viewing angle deviation in the second direction (Y-axis direction) (or the up and down direction) may be reduced, and a luminance maintenance rate and a color retention rate may be maintained at the same level in the up and down direction.

The display apparatus 100 according to one embodiment of the present disclosure may have a structure in which a subpixel SP having an opening area OPA of a wide width and a subpixel SP having an opening area OPA of a narrow width are alternately repeated. That is, the width of the opening area OPA may be widened or narrowed depending on each color of the subpixels SP. When the opening area OPA has different widths, the same current may be applied to generate the same luminance. Therefore, in case of the subpixel SP having an opening area OPA of a wide width, a density of the current applied to the light emitting layer 116 is lowered. This current density is associated with an afterimage lifespan. In this case, the afterimage means a phenomenon in which luminance is lowered by degradation applied to the light emitting layer 116. Therefore, the display apparatus 100 according to one embodiment of the present disclosure is provided so that the opening area OPA of one or two subpixels SP of four subpixels SP has a wide width, whereby degradation applied to the light emitting layer 116 may be reduced to improve an afterimage lifespan.

According to the present disclosure, the following advantageous effects may be obtained.

In the display apparatus according to the present disclosure, the reflective portion is provided in the periphery of the non-light emission area, so that the light may be extracted even from the non-light emission area, whereby overall light efficiency may be improved.

In the display apparatus according to the present disclosure, since the light may be extracted even from the non-light emission area, the display apparatus according to the present disclosure may have the same light emission efficiency or more improved light emission efficiency even with low power as compared with the display apparatus having no reflective portion, whereby overall power consumption may be reduced.

In the display apparatus according to the present disclosure, each of the plurality of subpixels includes the light extraction portion that includes the plurality of concave portions, so that light extraction efficiency of the light emitted from the light emitting element layer may be further improved.

In the display apparatus according to the present disclosure, since the reflective portion is disposed in the non-light emission area adjacent to the corner portion of the light emission area, the light may be extracted even from the non-light emission area adjacent to the corner portion of the light emission area, whereby light emission efficiency may be increased.

In the display apparatus according to the present disclosure, the aperture ratio of at least one subpixel may be increased through arrangement of lines for allowing the plurality of subpixels to emit light, and luminance and/or viewing angle deviation may be reduced or minimized.

In the display apparatus according to the present disclosure, since the aperture ratio of at least one of the plurality of subpixels may be increased, the afterimage lifespan of the light emitting layer may be improved.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is intended that all variations or modifications derived from the meaning, scope and equivalent concept described within the scope of the present disclosure.

The various embodiments described above can be combined to provide further embodiments. All of the U.S. patents. U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate having a plurality of pixels, each of the plurality of pixels having a plurality of subpixels;
a pattern portion on the substrate;
a reflective portion on the pattern portion; and
a plurality of lines provided below the pattern portion, for driving the plurality of subpixels,
wherein the plurality of subpixels includes a light emission area and a non-light emission area adjacent to the light emission area,
wherein the non-light emission area includes a first area adjacent to the light emission area and a second area adjacent to the first area, and the first area is between the second area and the light emission area, and
wherein at least one of the plurality of lines at least partially overlap the second area.

2. The display apparatus of claim 1, wherein the pattern portion surrounds the light emission area, and at least a portion of the reflective portion surrounds the light emission area.

3. The display apparatus of claim 2, wherein the pattern portion includes a concave shape and is between the plurality of subpixels, and the reflective portion is disposed along a profile of the pattern portion including a concave shape.

4. The display apparatus of claim 1, wherein the at least one of the plurality of lines overlaps the second area of one subpixel of the plurality of subpixels.

5. The display apparatus of claim 4, wherein the plurality of lines include:
a first line having a first width;
a second line having a second width wider than the first width; and
a third line having a third width wider than the second width, and
wherein the first line and the third line overlap the second area of the one subpixel.

6. The display apparatus of claim 5, wherein the second line and the third line overlap the first area and a portion of the light emission area of another subpixel of the plurality of subpixels.

7. The display apparatus of claim 6, wherein a length of the second line overlapped with the light emission area of the another subpixel is the same as that of the third line overlapped with the light emission area of the another subpixel.

8. The display apparatus of claim 6, wherein the second line and the third line have light reflectance of 90% or more.

9. The display apparatus of claim 5, wherein the first line and the second line are data lines, and the third line is a pixel power line or a reference line.

10. The display apparatus of claim 4, wherein the plurality of subpixels include:
a first subpixel emitting red light;
a second subpixel adjacent to the first subpixel and emitting white light;
a third subpixel adjacent to the second subpixel and emitting blue light; and
a fourth subpixel adjacent to the third subpixel and emitting green light, and
wherein the plurality of lines overlaps the second area in the first subpixel and the third subpixel.

11. The display apparatus of claim 10, wherein the plurality of lines overlaps the first area and a portion of the light emission area in the second subpixel and the fourth subpixel.

12. The display apparatus of claim 11, wherein each of the plurality of subpixels further include an opening area partitioned by the plurality of lines, and
wherein a width of the opening area of the first subpixel is greater than that of the opening area of the second subpixel.

13. The display apparatus of claim 12, wherein a width of the opening area of the third subpixel is greater than that of the opening area of the fourth subpixel.

14. The display apparatus of claim 12, wherein the width of the opening area of the first subpixel is the same as that of the opening area of the third subpixel, and
wherein the width of the opening area of the second subpixel is the same as that of the opening area of the fourth subpixel.

15. The display apparatus of claim 5, wherein the plurality of lines further includes a fourth line disposed in a direction crossing the first line, and
wherein the fourth line is disposed to overlap a portion of the first area of at least one of the plurality of subpixels and a portion of the light emission area of the at least one of the plurality of subpixels, or is disposed to overlap only the second area of the at least one of the plurality of subpixels.

16. The display apparatus of claim 4, further comprising a bank in each of the plurality of subpixels,
wherein the bank is disposed in the first area, and
wherein the second area is between the banks in the respective subpixels.

17. The display apparatus of claim 4, further comprising a light emitting element layer in the plurality of subpixels,
wherein the light emitting element layer includes:
a pixel electrode in the light emission area;
a light emitting layer on the pixel electrode and the non-light emission area; and
a reflective electrode on the light emitting layer, and
wherein the reflective portion is a portion of the reflection electrode.

18. The display apparatus of claim 4, wherein the pattern portion is spaced apart from the light emission area.

19. The display apparatus of claim 4, wherein a width of the pattern portion is reduced from the reflection portion toward the substrate.

20. The display apparatus of claim 1, further comprising a light extraction portion in each of the plurality of subpixels,
wherein the light extraction portion overlaps the light emission area and includes a plurality of concave portions,
wherein the light extraction portion is adjacent to the pattern portion, and
wherein the pattern portion includes an inclined surface disposed in the first area and a bottom surface extended from the inclined surface and disposed up to the second area.

21. The display apparatus of claim 20, wherein the inclined surface of the pattern portion forms an obtuse angle with the bottom surface of the pattern portion.

22. The display apparatus of claim 20, further comprising an overcoat layer on the substrate and a pixel electrode on the overcoat layer in each of the plurality of subpixels,
wherein the overcoat layer includes a first layer including the plurality of concave portions, and a second layer between the first layer and the pixel electrode, and
wherein the second layer is extended to the first area and is in contact with only a portion of the bottom surface of the pattern portion while covering the inclined surface of the pattern portion.

23. The display apparatus of claim 22, further comprising a bank covering an edge of the pixel electrode,
wherein the bank covers the second layer covering the inclined surface and is in contact with only a portion of the bottom surface of the pattern portion.

24. The display apparatus of claim 23, wherein each of the second layer and the bank on the bottom surface of the pattern portion is discontinuous.

25. A display apparatus comprising:
a substrate having a plurality of pixels, each of the plurality of pixels having a plurality of subpixels;
a pattern portion on the substrate;
a reflective portion on the pattern portion; and
a plurality of lines provided below the pattern portion, for driving the plurality of subpixels,
wherein the plurality of subpixels includes a light emission area and an opening area overlapped with the light emission area between the plurality of lines, and
wherein a width of the opening area of one subpixel of the plurality of subpixels is wider than that of the light emission area of the one subpixel.

26. The display apparatus of claim 25, wherein the pattern portion surrounds the light emission area, and at least a portion of the reflective portion surrounds the light emission area.

27. The display apparatus of claim 26, wherein the pattern portion includes a concave shape and is between the plurality of subpixels, and the reflective portion is disposed along a profile of the pattern portion including a concave shape.

28. The display apparatus of claim 25, wherein the width of the opening area of another subpixel of the plurality of subpixels is narrower than that of the light emission area of the another subpixel.

29. The display apparatus of claim 28, wherein the one subpixel and the another subpixel are disposed to be adjacent to each other.

30. The display apparatus of claim 28, wherein the plurality of lines include:
a first line having a first width;
a second line having a second width wider than the first width; and
a third line having a third width wider than the second width, and
wherein the opening area of the one subpixel is between the first line and the third line, and
wherein the opening area of the another subpixel is between the second line and the third line.

31. The display apparatus of claim 30, wherein a length of the second line overlapped with the light emission area of the another subpixel is the same as that of the third line overlapped with the light emission area of the another subpixel.

32. The display apparatus of claim 30, wherein the second line and the third line have light reflectance of 90% or more.

33. The display apparatus of claim 30, wherein the first line and the second line are data lines, and the third line is a pixel power line or a reference line.

34. The display apparatus of claim 28, wherein the plurality of subpixels include:
a first subpixel emitting red light;
a second subpixel adjacent to the first subpixel and emitting white light;
a third subpixel adjacent to the second subpixel and emitting blue light; and
a fourth subpixel adjacent to the third subpixel and emitting green light, and
wherein the one subpixel is either the first subpixel or the third subpixel, and
wherein the another subpixel is either the second subpixel or the fourth subpixel.

35. The display apparatus of claim 25, further comprising a light extraction portion in each of the plurality of subpixels,
wherein the light extraction portion overlaps the light emission area and includes a plurality of concave portions,
wherein the light extraction portion is adjacent to the pattern portion, and
wherein the pattern portion includes an inclined surface disposed in a first area adjacent to the light emission area and a bottom surface extended from the inclined surface and disposed up to a second area adjacent to the first area and spaced apart from the light emission area.

36. The display apparatus of claim 35, further comprising an overcoat layer on the substrate and a pixel electrode on the overcoat layer in each of the plurality of subpixels,
wherein the overcoat layer includes a first layer including the plurality of concave portions, and a second layer between the first layer and the pixel electrode, and
wherein the second layer is extended to the first area and is in contact with only a portion of the bottom surface of the pattern portion while covering the inclined surface of the pattern portion.

37. The display apparatus of claim 1, wherein based on the light emission area of each of the plurality of subpixels, the plurality of lines is disposed in a symmetric position.
